(19) United States
(12) Patent Application Publication
(10) Pub. No.: US 2026/0104148 A1
(43) Pub. Date: Apr. 16, 2026

(54) REALISTIC NEON-REPLICA LED LIGHTING

(71) Applicant: LED Inspirations, LLC, Houston, TX (US)

(72) Inventors: Nicholas William Senofsky, Cypress, TX (US); Michael T. Hadank, Midlothian, VA (US)

(21) Appl. No.: 19/183,481

(22) Filed: Apr. 18, 2025

Related U.S. Application Data
(63) Continuation of application No. PCT/US2025/024487, filed on Apr. 14, 2025.
(60) Provisional application No. 63/707,048, filed on Oct. 14, 2024.

(51) Int. Cl. F21S 4/26; F21V 5/00; F21V 9/32; F21Y 103/10; F21Y 107/90; F21Y 113/13; F21Y 115/10

(52) U.S. Cl. CPC F21S 4/26; F21V 5/00; F21V 9/32; H05K 1/144; F21Y 2103/10; F21Y 2107/90; F21Y 2113/13; F21Y 2115/10

(57) ABSTRACT

A realistic neon-replica LED lighting system replicates the iconic appearance of conventional neon lights without their inherent drawbacks. The system includes a flexible light engine, an optional flexible binder sleeve disposed over the flexible LED light engine, an optional flexible diffuser sleeve disposed over the optional flexible binder sleeve or the flexible LED light engine, and a rigid non-glass transparent tube disposed over the optional flexible diffuser sleeve, the optional flexible binder sleeve, and/or the flexible LED light engine. The rigid non-glass transparent tube is pliable capable of being shaped when heated to its glass transition temperature and returns to rigidity when cooled. The realistic neon-replica LED lighting system replicates the classic look of conventional neon light and is capable of repairing an existing conventional neon light installation in a seamless manner that can co-exist next to the functional portions of the conventional neon, such that it is virtually indistinguishable.

### CROSS REFERENCE TO RELATED APPLICATIONS

This application is a bypass continuation of PCT International Application PCT/US2025/024487, filed on Apr. 14, 2025, which claims the benefit of, and priority to, U.S. Provisional Patent Application Ser. No. 63/707,048, filed on Oct. 14, 2024, both of which are hereby incorporated by reference in their entirety for all purposes.

### FIELD OF THE INVENTION

The present invention relates to LED-based lighting systems that realistically replicate the aesthetic appearance of conventional neon lights without their many drawbacks, enabling repair of damaged portions of conventional neon lights with realistic neon-replica LED lighting and the creation of standalone realistic neon-replica LED lighting, that are virtually indistinguishable from conventional neon lights.

### BACKGROUND OF THE INVENTION

Neon lights are made of a sealed glass tube that is meticulously shaped into a desired design and then filled with high-purity noble gas. High-voltage electrodes are disposed at each distal end of the glass tube and step up the voltage to the thousands of volts required for the electrodes to conduct an electric current through the gas-filled glass tube. This electric current ionizes the gas atoms within the glass tube, creating positively charged ions and free electrons. As the electric current continues to flow, the free electrons collide with the gas atoms, transferring energy and causing the electrons to move to higher energy levels in a process known as excitation. The excited electrons are unstable at higher energy levels and eventually return to their original lower energy levels, known as the ground state. As they return to ground, they release the excess energy absorbed during excitation in the form of visible light. This process creates a vibrant and colorful glow that distinguishes neon lights from other lights. Although commonly referred to as “neon” lights, other noble gases may be used and the color of the visible light emitted depends on the unique energy levels of the electrons of the specific noble gas used in a given application. For example, neon gas produces bright red-orange light, but helium gas produces pale yellow or pinkish-orange light, argon gas produces light blue or pale lavender light, krypton gas produces pale white or whiteish-blue light, and xenon gas produces blue or blue-white light.

In conventional neon lights, the sealed glass tube is typically transparent and uncoated, allowing light to emanate in all directions, creating a three-dimensional effect, regardless of the viewer's vantage point. The light appears to be suspended within the transparent glass tube, giving the illusion of light floating in air. This combination of the transparent glass tube, the emission of visible light in all directions from the electrified noble gas inside, and the visual effect of light suspended within the transparent glass tube, produces the well-known, readily identifiable, and iconic visual appearance of conventional neon lights. However, the color of the emitted light is limited to the natural color created by excitation of the specific noble gas used.

In a common variation on conventional neon lights, a greater diversity of colors may be achieved by coating the interior of the sealed glass tube with phosphors. When the noble gas inside the glass tube is excited, it emits ultraviolet (“UV”) radiation that is not visible to the human eye. However, the phosphor coating absorbs the UV radiation and re-emits it as visible light whose hue is influenced by the composition of the phosphors. In this variation, argon gas is typically used to produce a vibrant blue hue and its UV radiation interacts with the phosphor coating to generate visible light. Different phosphors or combinations of phosphors may be used to produce colors that are different than those produced by excitation of the noble gases alone. However, the use of phosphor coatings results in an appearance that is somewhat less three-dimensional than conventional neon lights and the visual effect of light floating in air is diminished.

In another common variation on conventional neon lights, instead of coating the interior of the glass tube with phosphors, the exterior of the tube may be coated with the desired color. This exterior coating creates a filtered light effect, with the color of light emitted largely determined by the color of the coating. While this variation uniquely maintains its color even when unpowered, the visual appearance is less three-dimensional than conventional neon lights and the visual effect of light floating in air is virtually eliminated.

While conventional neon lights are ubiquitous and remain in widespread use, the manufacture, operation, and maintenance of conventional neon lights are complex, difficult, and expensive. Worse still, the repair of existing installations of conventional neon lights is exceptionally difficult and cost prohibitive, if even possible at all, due to constraints in the supply chain and the lack of skilled artisans.

### BRIEF SUMMARY OF THE INVENTION

According to one aspect of one or more embodiments of the present invention, a neon-replica LED lighting system includes a flexible LED light engine, and a rigid non-glass transparent tube disposed over the flexible LED light engine. The rigid non-glass transparent tube is pliable when heated to its glass transition temperature and returns to rigidity when cooled.

According to one aspect of one or more embodiments of the present invention, a method of making a neon-replica LED lighting system includes disposing a rigid non-glass transparent tube over a flexible LED light engine, heating at least a portion of the rigid non-glass transparent tube to its glass transition temperature to make at least a portion of it pliable, and shaping at least a portion of the pliable non-glass transparent tube while heated. The pliable non-glass transparent tube returns to rigidity when cooled.

Other aspects of the present invention will be apparent from the following description and claims.

### BRIEF DESCRIPTION OF THE DRAWINGS

FIG. 1A shows a conventional single-sided, single-row, single-color Light-Emitting-Diode (“LED”) strip light with an optional flexible phosphor and/or diffuser layer.

FIG. 1B shows a back-to-back arrangement of two conventional single-sided, single-row, single-color LED strip lights in accordance with one or more embodiments of the present invention.

FIG. 1C shows a distal-end view of the back-to-back arrangement of two conventional single-sided, single-row, single-color LED strip lights in accordance with one or more embodiments of the present invention.

FIG. 2A shows a conventional single-sided, single-row, multi-color LED strip light with an optional flexible diffuser layer.

FIG. 2B shows a back-to-back arrangement of two conventional single-sided, single-row, multi-color LED strip lights in accordance with one or more embodiments of the present invention.

FIG. 2C shows a distal-end view of the back-to-back arrangement of two conventional single-sided, single-row, multi-color LED strip lights in accordance with one or more embodiments of the present invention.

FIG. 3A shows a conventional double-sided, single-row, multi-color LED strip light with an optional flexible diffuser layer.

FIG. 3B shows a distal-end view of the conventional double-sided, single-row, multi-color LED strip light.

FIG. 4A shows a conventional single-sided, dual-row, single-color or multi-color LED strip light with an optional flexible phosphor and/or diffuser layer.

FIG. 4B shows a folded arrangement of a conventional single-sided, dual-row, single-color or multi-color LED strip light in accordance with one or more embodiments of the present invention.

FIG. 4C shows a distal-end view of the folded arrangement of the conventional single-sided, dual-row, single-color or multi-color LED strip light in accordance with one or more embodiments of the present invention.

FIG. 5A shows a perspective view of a first exemplary embodiment of a realistic neon-replica LED lighting system in accordance with one or more embodiments of the present invention.

FIG. 5B shows a detailed view of the first exemplary embodiment of a realistic neon-replica lighting system in accordance with one or more embodiments of the present invention.

FIG. 5C shows a cross-sectional view of the first exemplary embodiment of a realistic neon-replica lighting system in accordance with one or more embodiments of the present invention.

FIG. 6A shows a perspective view of a second exemplary embodiment of a realistic neon-replica LED lighting system in accordance with one or more embodiments of the present invention.

FIG. 6B shows a detailed view of the second exemplary embodiment of a realistic neon-replica lighting system in accordance with one or more embodiments of the present invention.

FIG. 6C shows a cross-sectional view of the second exemplary embodiment of a realistic neon-replica lighting system in accordance with one or more embodiments of the present invention.

FIG. 7A shows a perspective view of a third exemplary embodiment of a realistic neon-replica LED lighting system in accordance with one or more embodiments of the present invention.

FIG. 7B shows a detailed view of the third exemplary embodiment of a realistic neon-replica lighting system in accordance with one or more embodiments of the present invention.

FIG. 7C shows a cross-sectional view of the third exemplary embodiment of a realistic neon-replica lighting system in accordance with one or more embodiments of the present invention.

FIG. 8A shows a perspective view of a fourth exemplary embodiment of a realistic neon-replica LED lighting system in accordance with one or more embodiments of the present invention.

FIG. 8B shows a detailed view of the fourth exemplary embodiment of a realistic neon-replica lighting system in accordance with one or more embodiments of the present invention.

FIG. 8C shows a cross-sectional view of the fourth exemplary embodiment of a realistic neon-replica lighting system in accordance with one or more embodiments of the present invention.

FIG. 9A shows an example of a conventional neon light.

FIG. 9B shows a forming jig for shaping a realistic neon-replica LED lighting system in accordance with one or more embodiments of the present invention.

FIG. 9C shows the introduction of a realistic neon-replica LED lighting system to the forming jig in anticipation of shaping in accordance with one or more embodiments of the present invention.

FIG. 9D shows the application of heat to the realistic neon-replica LED lighting system in anticipation of shaping a first exemplary bend in accordance with one or more embodiments of the present invention.

FIG. 9E shows the application of heat to the realistic neon-replica LED lighting system in anticipation of shaping a second exemplary bend in accordance with one or more embodiments of the present invention.

FIG. 9F shows the application of heat to the realistic neon-replica LED lighting system in anticipation of shaping a third exemplary bend in accordance with one or more embodiments of the present invention.

FIG. 9G shows the realistic neon-replica LED lighting system replicating the conventional neon light of FIG. 9A in accordance with one or more embodiments of the present invention.

FIG. 10A shows a recessed forming board for making a realistic neon-replica LED lighting system in accordance with one or more embodiments of the present invention.

FIG. 10B shows a heating tube for heating the realistic neon-replica LED lighting system in accordance with one or more embodiments of the present invention.

FIG. 10C shows a heated and pliable realistic neon-replica LED lighting system in accordance with one or more embodiments of the present invention.

FIG. 10D shows the heated and pliable realistic neon-replica LED lighting system being introduced to the recesses of the recessed forming board to provide the exemplary shape in accordance with one or more embodiments of the present invention.

FIG. 10E shows the realistic neon-replica LED lighting system replicating the conventional neon light of FIG. 9A in accordance with one or more embodiments of the present invention.

### DETAILED DESCRIPTION OF THE INVENTION

One or more embodiments of the present invention are described in detail with reference to the accompanying figures. For consistency, like elements in the various figures are denoted by like reference numerals. In the following detailed description of the present invention, specific details are described to provide a thorough understanding of the present invention. In other instances, aspects that are well-known to those of ordinary skill in the art are omitted to avoid obscuring the description of the present invention.

Despite the well-known, readily identifiable, and iconic appearance associated with conventional neon lights and their common variations, they suffer from several drawbacks that complicate their manufacture, operation, and maintenance. The process of manufacturing conventional neon lights is complex, time-consuming, and expensive. Skilled artisans, whose numbers have dwindled in recent years, must carefully and precisely bend glass tubes into specific shapes without breaking or collapsing the tube at the bend points that would otherwise prevent gas from flowing through the tube and lighting properly. Once shaped, high voltage electrodes are attached to each distal end of the glass tube. A vacuum removes as much air as possible from the glass tube, while applying a high voltage to the electrodes to burn off any remaining impurities and contaminants. Then the glass tube must be carefully filled with noble gas at the proper pressure and sealed to prevent the introduction of further impurities. This process often includes the introduction of hazardous materials, such as mercury, to enhance brightness, which requires careful handling to prevent exposure and minimize environmental impacts. This requires a high degree of expertise and manual dexterity limited to relatively few such skilled artisans. Further complicating their manufacture, conventional neon lights rely on high-purity noble gases, which are subject to supply chain disruptions, including those impacted by geopolitics. A significant amount of the world's neon supply has historically been sourced from Ukraine, which is currently at war, disrupting the primary supply chain. These factors and others combine to make the process of manufacturing conventional neon lights a difficult process that requires skilled artisans whose ranks have dwindled in recent years, careful handling of hazardous materials, and the successful navigation of complex supply chains.

Conventional neon lights also present significant safety concerns during their manufacture, operation, and maintenance. Neon lights require high voltages, typically in the range between 2,000 and 15,000 volts Alternating-Current (“AC”), to ionize the noble gas inside the sealed glass tube, posing a risk of electric shock or electrocution if not properly handled. The fragile glass tubes can easily break at any time during manufacture, operation, or maintenance, leading to potential injuries from broken glass and further risk of electric shock or electrocution. Additionally, some neon lights contain hazardous materials that pose a significant health hazard from unintentional exposure. Conventional neon lights also produce significant amount of heat, which poses a safety risk for anyone coming into contact with it and conventional neon lights are generally considered to be a fire hazard. This is especially true if placed near flammable materials or left on for extended periods of time, as is often the case of their use in bars, restaurants, movie theaters, amusement parks, and other retail establishments.

While conventional neon lights are ubiquitous, the ongoing maintenance, repair, and replacement of failed portions or entire neon lighting systems have proven problematic and often results in the decommissioning or abandonment of the lighting systems. As discussed above, conventional neon lights are difficult to manufacture, operate, and maintain. Worse still, the skilled artisans capable of doing such work are dwindling in number. These factors and others have rendered the ongoing operation and maintenance of conventional neon lights very difficult. In large-scale installations, like those often seen at movie theaters, amusement parks, and retail establishments, the large-scale installation is typically made of many smaller sections of conventional neon lights, such that the failure of just a small portion substantially diminishes the visual appearance of the entire installation. Prior art attempts at replicating conventional neon lights cannot, for a variety of reasons, accurately replicate the visual appearance of conventional neon lights and therefore are not suitable for the partial repair, replacement, or replication of conventional neon lights.

For example, conventional neon lights rely on the electrification of noble gas to generate light that is emitted uniformly in all directions from the cylindrical surface of the glass tube, covering a full 360 degrees along its circumference, excluding the ends. In many applications, conventional neon lights are mounted on standoffs on a reflective chrome fascia that reflects additional light enhancing the visual appearance. Prior art attempts at replicating conventional neon lights do not emit light in all directions and do not realistically replicate the visual appearance of conventional neon lights.

Conventional neon lights use glass tubes that are cylindrical in shape, where the glass tube is shaped into a desired design and emits light uniformly in all directions from the cylindrical surface of the glass tube. Prior art attempts at replicating conventional neon lights typically do not use cylindrical shapes, cannot be easily bent, and cannot emit light uniformly in all directions, and do not realistically replicate the visual appearance of conventional neon lights.

Conventional neon lights are shaped into a desired design through a complicated glass-bending process that contributes to its unique visual appearance. Prior art attempts at replicating conventional neon lights lack rigidity, cannot be shaped into the desired design, and cannot maintain that shape on their own. As such, they do not realistically replicate the visual appearance of conventional neon lights.

Conventional neon lights rely on the excitation of noble gas within a sealed glass tube to create the visual effect of glowing light that is suspended within the glass tube. While prior art attempts look somewhat like conventional neon lights, they have all fallen short of achieving this critical requirement and cannot replicate conventional neon lights. Prior art attempts at replicating conventional neon lights simply cannot replicate the visual effect of glowing light suspended within the glass tube and do not realistically replicate the visual appearance of conventional neon lights.

Accordingly, in one or more embodiments of the present invention, a realistic neon-replica LED lighting system replicates the well-known, readily identifiable, and iconic appearance of conventional neon lights and its common variations while eliminating virtually all of their drawbacks discussed above. Despite prior art attempts at replicating conventional neon lights, the realistic neon-replica LED lighting system of the claimed invention is the first and only replica that is virtually indistinguishable from conventional neon lights, even when viewed up close.

The realistic neon-replica LED lighting system is significantly easier, safer, and more cost-effective to manufacture, as it uses a low voltage LED light engine and durable components, eliminating the need for, and handling of, fragile glass tubes, high-voltage transformers, high-voltage electrodes, high-purity noble gases, and hazardous materials. The system uses a non-glass transparent tube that is more durable and significantly easier to shape into a desired form, without requiring the expertise of skilled glass-bending artisans. Additionally, the use of commonly available components simplifies acquisition, handling, and assembly, further reducing costs. The realistic neon-replica LED lighting system is also easier, safer, and most cost-effective to operate, as it does not use high voltage components, fragile glass, high-purity noble gases, or hazardous materials.

The realistic neon-replica LED lighting system consumes less power and dissipates less heat compared to conventional neon lights. Even in a state of failure, the system does not expose anyone to high voltages, broken glass, high-purity noble gases, or hazardous materials. Advantageously, a realistic neon-replica LED lighting system enables, for the very first time, the ability to repair part or all of an existing conventional neon light installation in a seamless manner that can co-exist next to the functional portions of the conventional neon light, such that it is virtually indistinguishable. Additionally, the realistic neon-replica LED lighting system can be used instead of conventional neon lights and the aesthetic quality of the replication is so high that it is virtually indistinguishable from conventional neon lights.

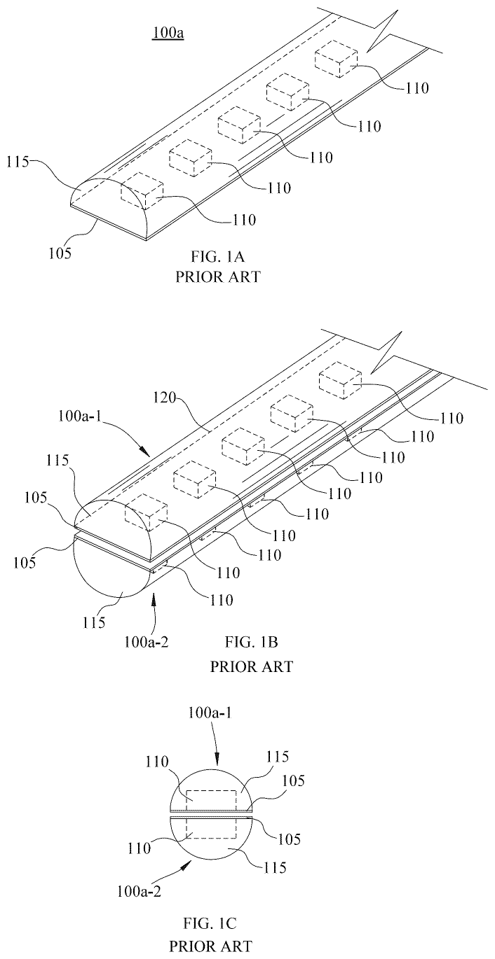

FIG. 1A shows a conventional single-sided, single-row, single-color LED strip light 100a with an optional flexible phosphor and/or diffuser layer 115. LED strip lights, including LED strip light 100a depicted in the figure, are versatile and energy-efficient lighting solutions, commonly used in residential and commercial applications. Each LED strip light 100a includes a plurality of single-color LEDs 110 arranged in a single-row and disposed on a single-side of a flexible substrate 105. Typically sold in reels (not shown), the user may cut the desired length of LED strip light 100a as needed for a given application or design. LED strip light 100a includes connector pads (not shown), typically disposed at pre-determined cut points (not shown) along the length of the strip light, for the connection of power leads (not shown) to one distal end of the LED strip light 100a. Single-color LED strip lights such as LED strip light 100a typically only require two electrical connections, one to the anode (not shown) and another to the cathode (not shown) of a low voltage Direct-Current (“DC”) power supply (not shown). The operating voltage is typically in a range between 5- and 24-volts DC.

In certain applications, an optional flexible phosphor and/or diffuser layer 115 may be applied on top of LED strip light 100a. In certain embodiments, layer 115 may include one or more phosphors that may be selected to achieve a desired color of emitted visible light. In other embodiments, layer 115 may include one or more diffusers that spread the light emitted by LEDs 110 evenly across the surface to eliminate what is typically referred to as hot spots and creates a smooth and continuous glow of light. In still other embodiments, layer 115 may include a combination of one or more phosphors that may be selected to achieve a desired color of emitted visible light and one or more diffusers that spread the light emitted by the LEDs 110 evenly across the surface to eliminate hot spots and create a smooth and continuous glow of light. The flexibility of optional flexible phosphor and/or diffuser layer 115 allows it to conform to the shape of LED strip light 100a, ensuring consistent light distribution even on curved or irregular surfaces. Additionally, optional flexible phosphor and/or diffuser layer 115 improves the durability and longevity of LED strip light 100a by providing a protective barrier against environmental factors, including moisture and dust.

Continuing, FIG. 1B shows a back-to-back arrangement of two conventional single-sided, single-row, single-color LED strip lights 100a-1, 100a-2 in accordance with one or more embodiments of the present invention. The beam angle of an LED strip light refers to the angle at which light is emitted relative to its substrate. This angle determines how narrow or wide the light is spread. A smaller beam angle results in a more focused and brighter light that covers a smaller area, while a larger beam angle spreads the light over a wider area but with less intensity. Conventional single-sided, single-row, single-color LED strip lights (e.g., 100a-1, 100a-2) typically have a beam angle in a range between 120 and 180 degrees.

Continuing, FIG. 1C shows a distal-end view of a back-to-back arrangement of two conventional single-sided, single-row, single-color LED strip lights 100a-1, 100a-2 with optional flexible phosphor and/or diffuser layers 115 in accordance with one or more embodiments of the present invention. Because each individual single-sided single-color LED strip light 100a-1, 100a-2 has a beam angle of at most 180 degrees, two LED strip lights 100a-1, 100a-2 may be arranged back-to-back as shown with their respective LEDs 110 facing in opposing directions to enhance the beam angle of the emitted light from the back-to-back arrangement. In applications where each single-sided, single-row, single-color LED strip 100a-1, 100a-2 has a beam angle of 180 degrees, arranging two single-sided, single-row, single-color LED strip lights 100a-1, 100a-2 back-to-back increases the beam angle to a full 360 degrees about its circumference.

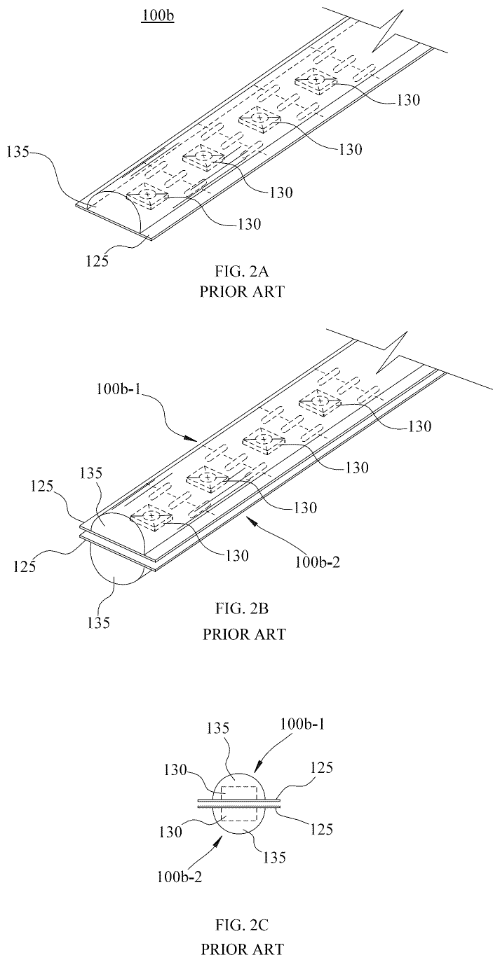

FIG. 2A shows a conventional single-sided, single-row, multi-color LED strip light 100b with an optional flexible diffuser layer 135. While conventional single-color LEDs (e.g., 110 of FIG. 1) are only capable of emitting a single color of visible light, a multi-color LED 130 combines independently controllable red, green, and blue diodes (not independently illustrated) in a single package, enabling the production of more than 16 million different colors. Each LED strip light 100b includes a plurality of multi-color LEDs 130 arranged in a single-row and disposed on a single-side of a flexible substrate 125. Typically sold in reels (not shown), the user may cut the desired length of LED strip light as needed for a given application or design. LED strip lights 100b include connector pads (not shown), typically disposed at pre-determined cut points (not shown) along the length of the reel (not shown), for the connection of power leads (not shown) to one distal end of the LED strip light 100b. Multi-color LED strip lights 100b typically require three or more leads depending on the type or kind of multi-color LED as is well known in the art, often including a common anode (not shown) or cathode (not shown) of a low voltage DC power supply (not shown), typically with an operating voltage in a range between 5- and 24-volts DC, and independent control lines for the red, green, and blue diodes of LEDs 130. In certain applications, an optional flexible diffuser layer 135 may be applied on top of LED strip light 100b. Layer 135 may include one or more diffusers that spread the light emitted by LEDs 130 evenly across the surface to eliminate hot spots and creates a smooth and continuous glow of light. The flexibility of optional flexible diffuser layer 135 allows it to conform to the shape of LED strip light 100b, ensuring consistent light distribution even on curved or irregular surfaces. Additionally, optional flexible diffuser layer 135 improves the durability and longevity of LED strip light 100b by providing a protective barrier against environmental factors, including moisture and dust.

Continuing, FIG. 2B shows a back-to-back arrangement of two conventional single-sided, single-row, multi-color LED strip lights 100b-1, 100b-2 with optional flexible diffuser layers 135 in accordance with one or more embodiments of the present invention. Each conventional single-sided multi-color LED strip light (e.g., 100b-1, 100b-2) typically has a beam angle in a range between 120 and 180 degrees. When arranged back-to-back as shown, the beam angle of the arrangement may be enhanced.

Continuing, FIG. 2C shows a distal-end view of a back-to-back arrangement of two conventional single-sided, single-row, multi-color LED strip lights 100b-1, 100b-2 with optional flexible diffuser layers 135 in accordance with one or more embodiments of the present invention. Because each individual single-sided, single-row, multi-color LED strip light 100b-1, 100b-2 has a beam angle of at most 180 degrees, two LED strip lights 100b-1, 100b-2 may be arranged back-to-back as shown with their respective LEDs 130 facing in opposing directions to enhance the beam angle of the emitted light. In applications where each single-sided, single-row, multi-color LED strip 100b-1, 100b-2 has a beam angle of 180 degrees, arranging two single-sided, single-row, multi-color LED strip lights 100b-1, 100b-2 back-to-back increases the beam angle to a full 360 degrees about its circumference.

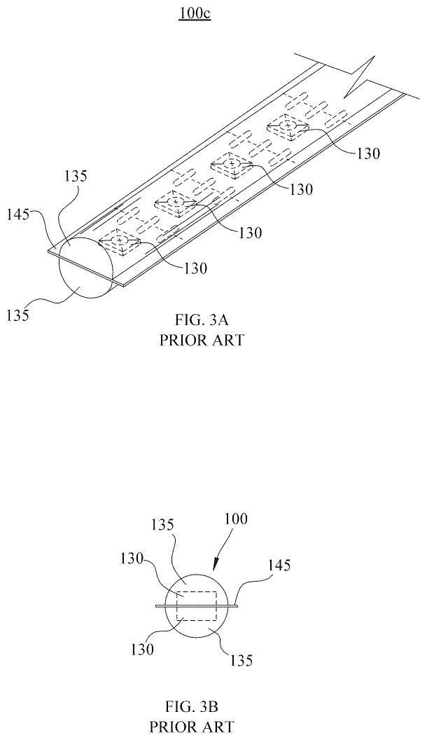

FIG. 3A shows a conventional double-sided, single-row, multi-color LED strip light 100c with an optional flexible diffuser layer 135. Multi-color LED strip light 100c includes a first plurality of multi-color LEDs 130 arranged in a single-row and disposed on a first side of a flexible substrate 145 and a second plurality of multi-color LEDs 130 arranged in a single-row and disposed on a second side of flexible substrate 145. Typically sold in reels (not shown), the user may cut the desired length of LED strip light 100c as needed for a given application or design. LED strip light 100c includes connector pads (not shown), typically disposed at pre-determined cut points (not shown) along the length of the reel (not shown), for the connection of power leads (not shown) and control leads (not shown). Multi-color LED strip lights 100c typically require three or more leads depending on the type or kind of multi-color LED as is well known in the art, often including a common anode (not shown) or cathode (not shown) of a low voltage DC power supply (not shown), typically with an operating voltage in a range between 5- and 24-volts DC, and independent control lines for the red, green, and blue diodes of LEDs 130.

Continuing, FIG. 3B shows a distal-end view of a conventional double-sided, single-row, multi-color LED strip light 100c. Because each individual side of double-sided, single-row, multi-color LED strip light 100c has a beam angle of at most 180 degrees, the disposition of multi-color LEDs 130 on both sides enhances the beam angle of the emitted light. In certain applications where each side of double-sided, single-row, multi-color LED strip light 100c has a beam angle of 180 degrees, the double-sided, single-row, multi-color LED strip light 100c increases the beam angle to a full 360 degrees about its circumference.

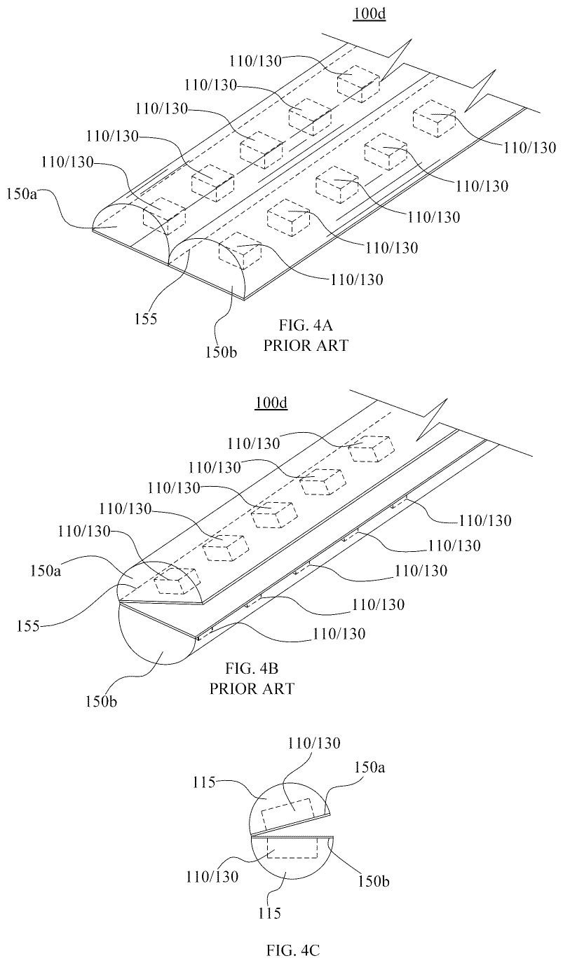

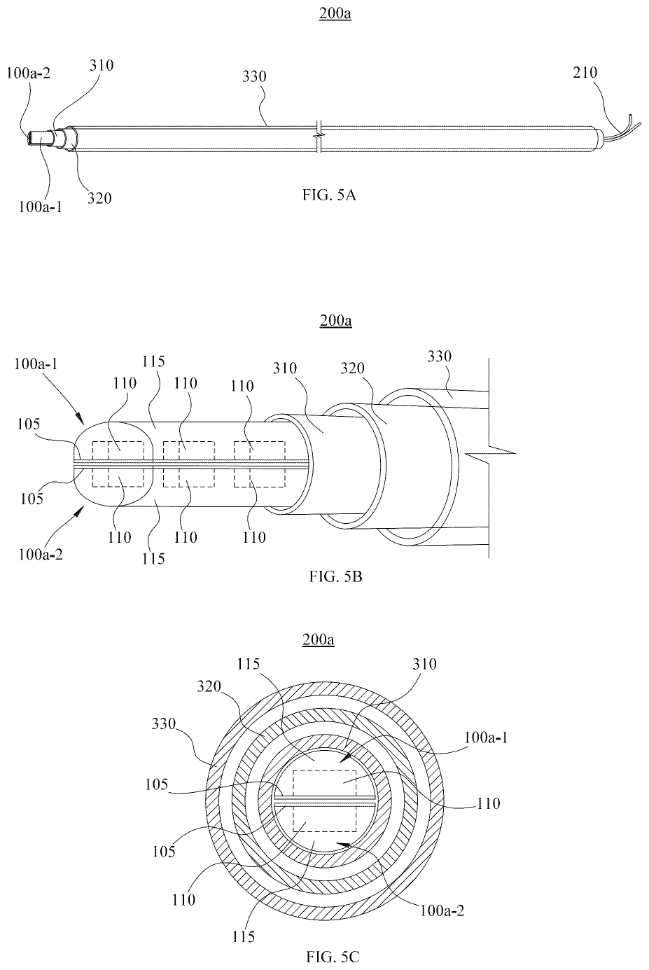

FIG. 4A shows a conventional single-sided, dual-row, single-color 110 or multi-color 130 LED strip light 100d with an optional flexible phosphor and/or diffuser layer 115. LED strip light 100d includes a first plurality of single-color 110 or multi-color 130 LEDs arranged in a first row and a second plurality of single-color 110 or multi-color 130 LEDs arranged in a second row, both of which are disposed on the same side of a flexible substrate 150. The first plurality of single-color 110 or multi-color 130 LEDs are arranged in the first row disposed on a left side 150a of a flexible bend line 155 of flexible substrate 150 and the second plurality of single-color 110 or multi-color 130 LEDs are arranged in the second row disposed on a right side 150b of the flexible bend line 155 of flexible substrate 150. Flexible substrate 150 may be bent or folded along longitudinal bend line 155.

Typically sold in reels (not shown), the user may cut the desired length of LED strip light 100d as needed for a given application or design. LED strip light 100d includes connector pads (not shown), typically disposed at pre-determined cut points (not shown) along the length of the strip light, for the connection of power leads (not shown) and/or control lines (not shown) to one distal end of LED strip light 100d. Single-color versions of LED strip lights 100d typically only require two electrical connections, one to the anode (not shown) and another to the cathode (not shown) of a low voltage DC power supply (not shown). The operating voltage is typically in a range between 5- and 24-volts DC. Multi-color versions of LED strip light 100d typically require a common anode (not shown) or cathode (not shown) of a low voltage DC power supply (not shown), typically with an operating voltage in a range between 5- and 24-volts DC, and independent control lines for the red, green, and blue diodes of multi-color LEDs 130.

In certain applications, optional flexible phosphor and/or diffuser layers 115 may be applied on top of each row of LEDs 110/130 of LED strip light 100d. In certain embodiments, each layer 115 may include one or more phosphors that may be selected to achieve a desired color of emitted visible light. In other embodiments, each layer 115 may include one or more diffusers that spread the light emitted by LEDs 110/130 evenly across the surface to eliminate hot spots and create a smooth and continuous glow of light. In still other embodiments, each layer 115 may include a combination of one or more phosphors that may be selected to achieve a desired color of emitted visible light and one or more diffusers that spread the light emitted by LEDs 110/130 evenly across the surface to eliminate hot spots and create a smooth and continuous glow of light. The flexibility of optional flexible phosphor and/or diffuser layers 115 allows them to conform to the shape of LED strip light 100d, ensuring consistent light distribution even on curved or irregular surfaces. Additionally, optional flexible phosphor and/or diffuser layers 115 improve the durability and longevity of LED strip light 100d by providing a protective barrier against environmental factors, including moisture and dust.

Continuing, FIG. 4B shows a folded back-to-back arrangement of the conventional single-sided, dual-row LED strip light 100d in accordance with one or more embodiments of the present invention. Conventional single-sided, dual-row, single-color 110 or multi-color 130 LED strip lights (e.g., 100d) typically have a beam angle in a range between 120 and 180 degrees. However, LED strip light 100d includes a first plurality of LEDs 110/130 arranged in a first row disposed on a left side 150a of a flexible longitudinal bend line 155 of flexible substrate 150 and a second plurality of LEDs 110/130 arranged in a second row disposed on a right side 150b of the flexible longitudinal bend line 155 of flexible substrate 150. When folded, each row of LEDs 110/130 is independently capable of a beam angle in a range between 120 and 180 degrees with respect to the portion of flexible substrate 150 on which it is disposed. As such, when flexible substrate 150 is folded along bend line 155, the rows of LEDs 110/130 are arranged back-to-back, similar to the back-to-back arrangement of two conventional single-sided, single-row LED strip lights (e.g., 100a-1/100a-2 or 100b-1/100b-2) or a double-sided, single row LED strip light (e.g., 100c), with respect to the generation of a 360 degree beam angle.

Continuing, FIG. 4C shows a distal-end view of the folded arrangement of the conventional single-sided, dual-row, single-color 110 or multi-color 130 LED strip light 100d in accordance with one or more embodiments of the present invention. Because the first plurality of single color 110 or multi-color 130 LEDs arranged in a first row and disposed on the left side 150a of flexible substrate 150 and the second plurality of single color 110 or multi-color 130 LEDs arranged in the second row and disposed on the right side 150b of flexible substrate 150 each have a beam angle of at most 180 degrees, when flexible substrate 150 of LED strip light 100d is folded along the longitudinal bend line 155, the left side and the right side may be arranged such that their respective single-color 110 or multi-color 130 LEDs are back-to-back and facing in opposing directions to enhance the beam angle of the emitted light. In applications where each side of folded LED strip light 100d has a beam angle of 180 degrees, the folded LED strip light 100d increases the beam angle to a full 360 degrees about its circumference.

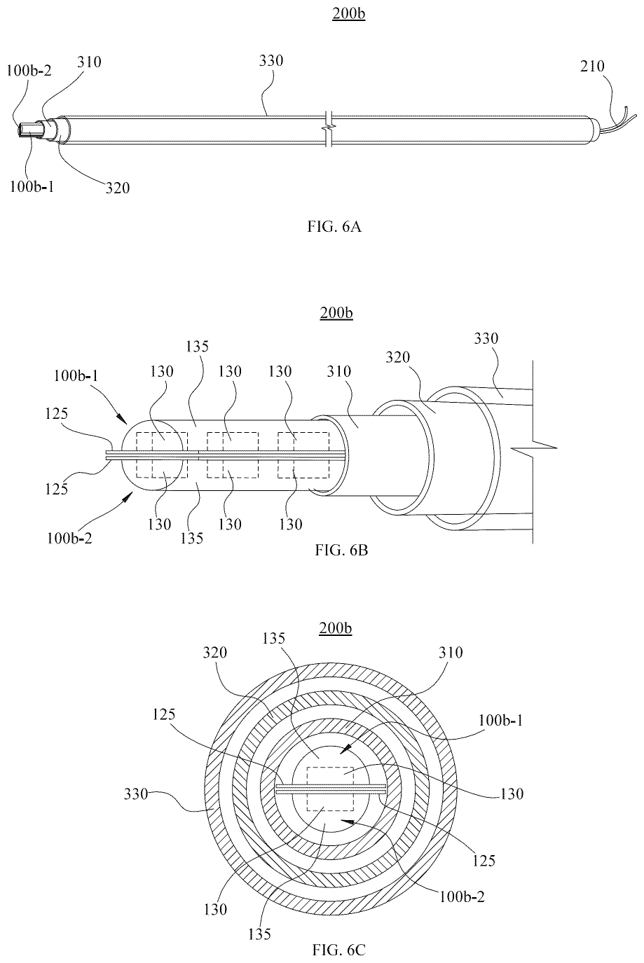

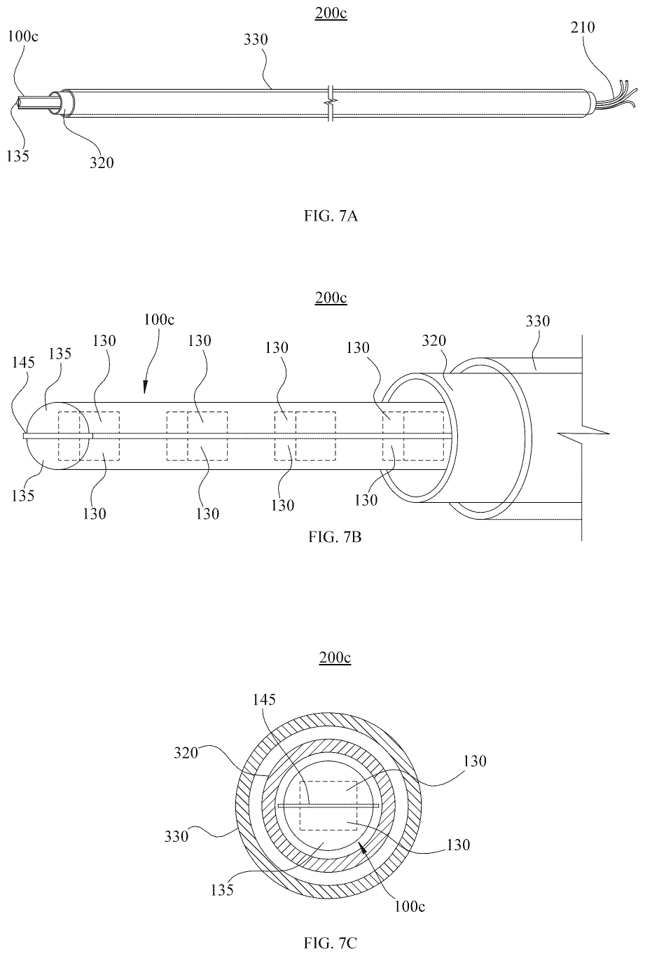

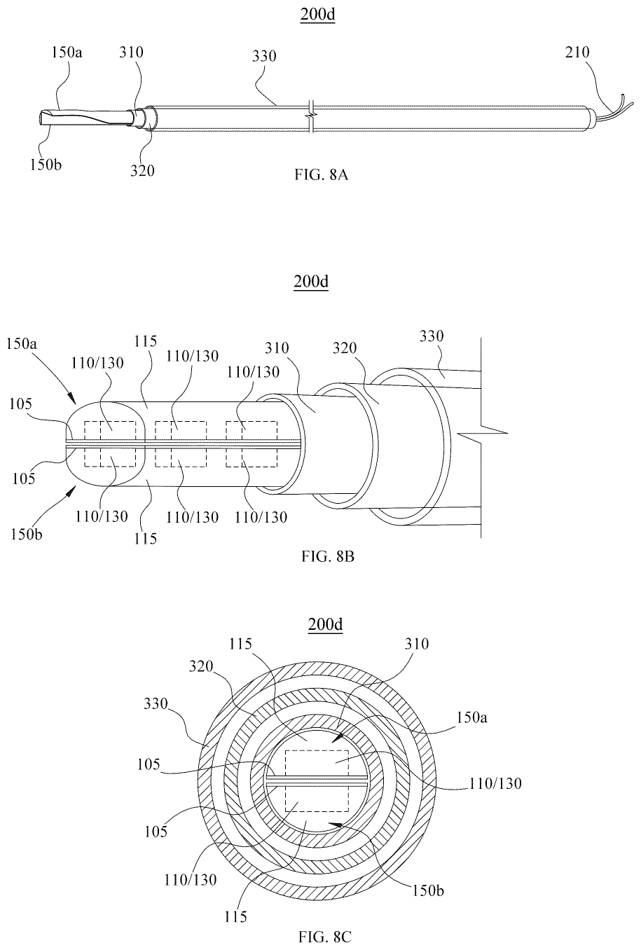

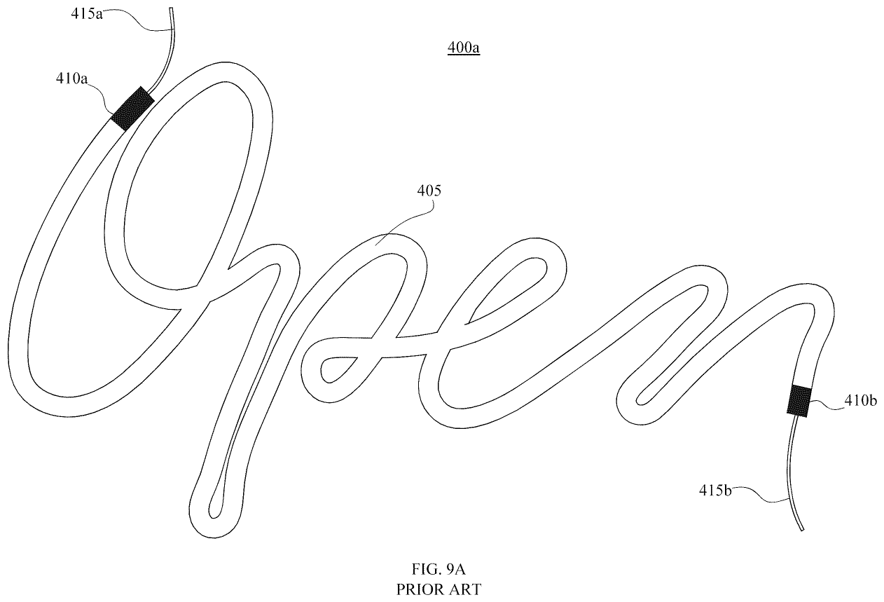

While the preceding paragraphs describe a few examples of the types and kinds of prior art LED strip lights (e.g., 100a, 100b, 100c, 100d) that may be used as part of a flexible LED light engine of a realistic neon-replica LED lighting system (e.g., 200a of FIG. 5, 200b of FIG. 6, 200c of FIG. 7, 200d of FIG. 8), one of ordinary skill in the art, having the benefit of this disclosure, will appreciate that there are many different types and kinds of LED strip lights that are well known in the art, such that their enumeration and description would overly complicate and obscure the description of the present invention. Notwithstanding, they could be used as part of a flexible LED light engine in accordance with one or more embodiments of the present invention.

As such, in one or more embodiments of the present invention, a flexible LED light engine of the present invention may use any type or kind of LED strip light, including, but not limited to, LED strip lights having a single row of LEDs (single-color or multi-color) disposed on a single-side of the flexible substrate (e.g., 100a of FIG. 1, 100b of FIG. 2), LED strip lights having a single row of LEDs (single-color or multi-color) disposed on both sides of a double-sided flexible substrate (e.g., 100c of FIG. 3), or LED strip lights having rows of LEDs (single-color or multi-color) disposed side-by-side on a single-side of the flexible substrate that is capable of being folded (e.g., 100d of FIG. 4). As noted above, in one or more embodiments of the present invention, a flexible LED light engine of the present invention may use single-color LEDs (e.g., 110 of FIG. 1) or multi-color LEDs (e.g., 130 of FIGS. 2 and 3). One of ordinary skill in the art will appreciate that multi-color LEDs may include, but are not limited to, Red-Green-Blue (“RGB”) LEDs, Red-Green-Blue-White (“RGBW”) LEDs, Red-Green-Blue-warm White-cool White (“RGBWW”) LEDs, Red-Green-Blue-Correlated-Color-Temperature (“RGBCCT”) LEDS, individually addressable RGB LEDs, sometimes referred to as pixel LEDs or SPI Digital LED Tape Light, and others that are well known in the art. Additionally, some embodiments may include an optional flexible phosphor and/or diffuser layer (e.g., 115 of FIGS. 1 and 4) or an optional diffuser layer (e.g., 135 of FIGS. 2 and 3) disposed over each row of LEDs 110/130.

FIG. 5A shows a perspective view of a first exemplary embodiment 200a of a realistic neon-replica LED lighting system in accordance with one or more embodiments of the present invention. Realistic neon-replica LED lighting system 200a may include a flexible LED light engine (e.g., 100a-1, 100a-2 arranged back-to-back), an optional flexible binder sleeve 310 disposed over the flexible LED light engine (e.g., 100a-1, 100a-2), an optional flexible diffuser sleeve 320 disposed over optional flexible binder sleeve 310 and/or the flexible LED light engine (e.g., 100a-1, 100a-2), and a rigid non-glass transparent tube 330 disposed over optional flexible diffuser sleeve 320, optional flexible binder sleeve 310, and the flexible LED light engine (e.g., 100a-1, 100a-2).

While the flexible components of realistic neon-replica LED lighting system 200a are flexible by design, rigid non-glass transparent tube 330 is rigid at ambient temperature. When heated to its glass transition temperature, rigid non-glass transparent tube 330 becomes pliable and capable of being shaped and returns to rigidity when cooled to ambient temperature.

In certain embodiments, rigid non-glass transparent tube 330 may be composed of an acrylic material. Acrylic material used to create rigid non-glass transparent tube 330, may include, for example, polymethyl methacrylate (“PMMA”), that has a glass transition temperature in a range between 194 degrees and 239 degrees Fahrenheit. Notwithstanding, one of ordinary skill in the art, having the benefit of this disclosure, will appreciate that the material composition of the acrylic material may vary based on an application or design in accordance with one or more embodiments of the present invention. As discussed in more detail herein, in one or more embodiments of the present invention, rigid non-glass transparent tube 330 may include one or more color dyes and/or one or more diffusers that are dissolved into the acrylic material during formation of rigid non-glass transparent tube 330, typically by extrusion or casting, the content of which may vary the glass transition temperature.

In other embodiments, rigid non-glass transparent tube 330 may be composed of a polycarbonate material. Polycarbonate material may include, for example, bisphenol A (“BPA”) and phosgene (“COCl₂”) used to create rigid non-glass transparent tube 330 through a polymerization process, that has a glass transition temperature in a range between 284 degrees and 302 degrees Fahrenheit. Notwithstanding, one of ordinary skill in the art, having the benefit of this disclosure, will appreciate that the material composition of the polycarbonate material may vary based on an application or design in accordance with one or more embodiments of the present invention. As discussed in more detail herein, in one or more embodiments of the present invention, rigid non-glass transparent tube 330 may include one or more color dyes and/or one or more diffusers that are dissolved into the polycarbonate material during formation of rigid non-glass transparent tube 330, the content of which may vary the glass transition temperature.

As a single-color LED 110 embodiment, the flexible LED light engine (e.g., 100a-1, 100a-2) may include two electrical leads 210 on a single distal end for connection to the anode (not shown) and the cathode (not shown) of a conventional low voltage DC power supply (not shown), typically in a range between 5- and 24-volts DC. Realistic neon-replica LED lighting system 200a may be constructed having any desired length for a given application or design. Notwithstanding, one of ordinary skill in the art, having the benefit of this disclosure, will appreciate that realistic neon-replica LED lighting system 200a may be manufactured in predetermined lengths, each of which may be cut down in size for a specific application or design simply by cutting the desired length off the other distal end, similar to the manner in which a reel of LED strip light may be cut down in size for a given application or design.

Continuing, FIG. 5B shows a detailed view of the first exemplary embodiment 200a of a realistic neon-replica lighting system in accordance with one or more embodiments of the present invention. The flexible LED light engine (e.g., 100a-1, 100a-2) may include a first single-sided, single-row, single-color LED strip light 100a-1 having a first plurality of single-color LEDs 110 disposed on a single side of a first flexible substrate 105 and an optional first flexible phosphor and/or diffuser layer 115 disposed over the first plurality of single-color LEDs 110, a second single-sided, single-row, single-color LED strip light 100a-2 including a second plurality of single-color LEDs 110 disposed on a single side of a second flexible substrate 105 and an optional second flexible phosphor and/or diffuser layer 115 disposed over the second plurality of single-color LEDs 110. First 100a-1 and second 100a-2 single-sided, single-row, single-color LED strip lights may be arranged back-to-back with the first plurality of single-color LEDs 110 of 100a-1 and the second plurality of single-color LEDs 110 of 100a-2 facing in opposing directions as shown. Flexible binder sleeve 310 may be disposed over first 100a-1 and second 100a-2 single-sided, single-row LED strip lights to retain their back-to-back orientation (e.g., FIG. 5C).

In certain embodiments of the present invention, first single-sided, single-row, single-color LED strip light 100a-1 may include a first flexible phosphor layer 115 disposed over the first plurality of LEDs 110 and second single-sided, single-row, single-color LED strip light 100a-2 may include a second flexible phosphor layer 115 disposed over the second plurality of LEDs 110. Flexible phosphor layer 115 may include one or more phosphors sufficient to achieve the desired color of visible light emitted.

In other embodiments of the present invention, first single-sided, single-row, single-color LED strip light 100a-1 may include a first flexible diffuser layer 115 disposed over the first plurality of LEDs 110 and second single-sided, single-row, single-color LED strip light 100a-1 may include a second flexible diffuser layer 115 disposed over the second plurality of LEDs 110. Flexible diffuser layer 115 may include one or more diffusers sufficient to uniformly distribute the light, eliminate hot spots, and create a smooth and continuous glow of light. In such embodiments, optional flexible diffuser sleeve 320 may not be required if the integrated flexible diffuser layer 115 provides sufficient diffusion.

In still other embodiments of the present invention, first single-sided, single-row LED strip light 100a-1 may include a first flexible phosphor and diffuser layer 115 disposed over the first plurality of LEDs 110 and second single-sided, single-row, single-color LED strip light 100a-2 may include a second flexible phosphor and diffuser layer 115 disposed over the second plurality of LEDs 110. Flexible phosphor and diffuser layer 115 may include one or more phosphors sufficient to achieve the desired color of light and one or more diffusers sufficient to uniformly distribute the light, eliminate hot spots, and create a smooth and continuous glow of light. In such embodiments, optional flexible diffuser sleeve 320 may not be required as the flexible phosphor and diffuser layer 115 integrated with the LED strip lights 100a-1, 100a-2 may provide sufficient diffusion.

In each of the embodiments noted above, the one or more phosphors and the one or more diffusers may be embedded in flexible silicone to enhance the light quality and the light efficiency, while serving as a flexible and protective medium.

Continuing, FIG. 5C shows a cross-sectional view of a first exemplary embodiment 200a of a realistic neon-replica lighting system in accordance with one or more embodiments of the present invention. First 100a-1 and second 100a-2 single-sided, single-row, single-color LED strip lights of the flexible LED light engine (e.g., 100a-1, 100a-2) may be arranged in a back-to-back orientation as shown with the first plurality of single-color LEDs 110 of 100a-1 and the second plurality of single-color LEDs 110 of 100a-2 facing in opposing directions and held together in the back-to-back-orientation by optional flexible binder sleeve 310.

Optional flexible binder sleeve 310 may be disposed over first 100a-1 and second 100a-2 single-sided, single-row, single-color LED strip lights to retain their back-to-back orientation. In certain embodiments, flexible binder sleeve 310 may be composed of light transmissible heat-shrink tubing. In other embodiments, flexible binder sleeve 310 may be composed of light transmissible cold-shrink tubing. In still other embodiments, flexible binder sleeve 310 may be composed of light transmissible liquid electrical tape or other sealant. One of ordinary skill in the art, having the benefit of this disclosure, will recognize that flexible binder sleeve 310 may be composed of any other material that provides the requisite structure and light transmissibility while maintaining flexibility and may vary based on an application or design in accordance with one or more embodiments of the present invention.

Optional flexible diffuser sleeve 320 may be disposed over the optional flexible binder sleeve 310 and/or the flexible LED light engine (e.g., 100a-1, 100a-2) to uniformly distribute the light, eliminate hot spots, and create a smooth and continuous glow of light. In certain embodiments, flexible diffuser sleeve 320 may be composed of flexible silicone. In other embodiments, flexible diffuser sleeve 320 may be composed of flexible acrylic. In still other embodiments, flexible diffuser sleeve 320 may be composed of flexible polycarbonate or polyethylene terephthalate. One of ordinary skill in the art, having the benefit of this disclosure, will recognize that flexible diffuser sleeve 320 may be composed of any other material that provides the requisite diffusion while maintaining flexibility and may vary based on an application or design in accordance with one or more embodiments of the present invention.

Rigid non-glass transparent tube 330 may be disposed over optional flexible diffuser sleeve 320, optional flexible binder sleeve 310, and/or the flexible LED light engine (e.g., 100a-1, 100a-2), depending on the application or design.

In certain embodiments, non-glass transparent tube 330 may be composed of acrylic material such as, for example, PMMA, and be transparent, such that realistic neon-replica lighting system 200a replicates the visual appearance of light suspended in glass associated with conventional neon lights.

In other embodiments, non-glass transparent tube 330 may include one or more color dyes dissolved in the acrylic material during formation of non-glass transparent tube 330, by extrusion or casting, producing a transparent colored tube 330, replicating the visual appearance of phosphor-coated glass tubes associated with a common variation of conventional neon lights.

In still other embodiments, non-glass transparent tube 330 may include one or more color dyes and one or more diffusers dissolved in acrylic material during formation of non-glass transparent tube 330, by extrusion or casting, producing a translucent colored tube 330, replicating the visual appearance of exterior coated glass tubes associated with another common variation of conventional neon lights.

In certain embodiments, non-glass transparent tube 330 may be composed of polycarbonate material such as, for example, BPA and COCl₂, and be transparent, such that realistic neon-replica lighting system 200a replicates the visual appearance of light suspended in glass associated with conventional neon lights.

In other embodiments, non-glass transparent tube 330 may include one or more color dyes dissolved in the polycarbonate material during formation of non-glass transparent tube 330, by extrusion or casting, producing a transparent colored tube 330, replicating the visual appearance of phosphor-coated glass tubes associated with a common variation of conventional neon lights.

In still other embodiments, non-glass transparent tube 330 may include one or more color dyes and one or more diffusers dissolved in polycarbonate material during formation of non-glass transparent tube 330, producing a translucent colored tube 330, replicating the visual appearance of exterior coated glass tubes associated with another common variation of conventional neon lights.

In one or more embodiments of the present invention, realistic neon-replica LED lighting system 200a has a 360-degree beam angle. So long as each single-sided, single-row, single-color LED strip light 100a-1, 100a-2 (whether taken alone, with optional flexible phosphor and/or diffuser layers 115 disposed on LEDs 110, or in combination with optional flexible diffuser sleeve 320) has a beam angle of 180 degrees, the arrangement of two such LED strip lights 100a-1, 100a-2 back-to-back increases the effective beam angle of the flexible LED light engine (e.g., 100a-1, 100a-2) to 360 degrees, such that it closely mimics the visual appearance of light emanating from all directions of the glass tube of conventional neon lights.

Realistic neon-replica LED lighting system 200a may be rigid when assembled, but rigid non-glass transparent tube 330 may be heated until pliable to aesthetically shape realistic neon-replica LED lighting system 200a. Once it returns to ambient temperature, non-glass transparent tube 330 advantageously returns to rigidity and maintains its shaped form. In this way, realistic neon-replica LED lighting system 200a may be easily shaped into a desired shape or design without requiring the skill or expertise of a skilled glass-bending artisan or the dangerous and complicated process of manufacturing as is required with conventional neon lights. Instead, mere portions of non-glass transparent tube 330 may be heated to the glass transition temperature to become pliable enough to achieve the desired shape or design. Advantageously, realistic neon-replica LED lighting system 200a is rigid upon cooling to ambient temperature and fixedly retains its shape, is more durable, lighter, and consumes less power than conventional neon lights, and so closely replicates the appearance of 360-degree continuous glowing light suspended in glass that it is virtually indistinguishable from conventional neon lights.

FIG. 6A shows a perspective view of a second exemplary embodiment 200b of a realistic neon-replica LED lighting system in accordance with one or more embodiments of the present invention. Realistic neon-replica LED lighting system 200b may include a flexible LED light engine (e.g., 100b-1, 100b-2 arranged back-to-back), an optional flexible binder sleeve 310 disposed over the flexible LED light engine (e.g., 100b-1, 100b-2), an optional flexible diffuser sleeve 320 disposed over optional flexible binder sleeve 310 and/or the flexible LED light engine (e.g., 100b-1, 100b-2), and a rigid non-glass transparent tube 330 disposed over optional flexible diffuser sleeve 320, optional flexible binder sleeve 310, and the LED light engine (e.g., 100b-1, 100b-2).

While the flexible components of realistic neon-replica LED lighting system 200b are flexible by design, rigid non-glass transparent tube 330 is rigid at ambient temperature. However, when heated to its glass transition temperature, rigid non-glass transparent tube 330 becomes pliable and capable of being shaped and returns to rigidity when cooled.

In certain embodiments, rigid non-glass transparent tube 330 may be composed of an acrylic material. Acrylic material used to create rigid non-glass transparent tube 330, may include, for example, PMMA. that has a glass transition temperature in a range between 194 degrees and 239 degrees Fahrenheit. Notwithstanding, one of ordinary skill in the art, having the benefit of this disclosure, will appreciate that the material composition of the acrylic material may vary based on an application or design in accordance with one or more embodiments of the present invention. As discussed in more detail herein, in one or more embodiments of the present invention, rigid non-glass transparent tube 330 may include one or more color dyes and/or one or more diffusers that are dissolved into the acrylic material during formation of rigid non-glass transparent tube 330, typically by extrusion or casting, the content of which may vary the glass transition temperature.

In other embodiments, rigid non-glass transparent tube 330 may be composed of a polycarbonate material. Polycarbonate material may include, for example, BPA and COCl₂ used to create rigid non-glass transparent tube 330 through a polymerization process, that has a glass transition temperature in a range between 284 degrees and 302 degrees Fahrenheit. Notwithstanding, one of ordinary skill in the art, having the benefit of this disclosure, will appreciate that the material composition of the polycarbonate material may vary based on an application or design in accordance with one or more embodiments of the present invention. As discussed in more detail herein, in one or more embodiments of the present invention, rigid non-glass transparent tube 330 may include one or more color dyes and/or one or more diffusers that are dissolved into the polycarbonate material during formation of rigid non-glass transparent tube 330, the content of which may vary the glass transition temperature.

As a multi-color LED 130 embodiment, the flexible LED light engine (e.g., 100b-1, 100b-2) may include three or more leads depending on the type or kind of multi-color LED as is well known in the art, often including a plurality of electrical leads 210 on a single distal end for connection to the anode (not shown) or the cathode (not shown) of a conventional low voltage DC power supply (not shown), typically in a range between 5- and 24-volts DC, and the others for connection to the red, green, and blue diodes (not independently illustrated) of multi-color LEDs 130. The red, green, and blue diodes (not independently illustrated) of multi-color LEDs 130 are independently controllable such that the flexible LED light engine (e.g., 100b-1, 100b-2) can produce more than 16 million colors without requiring the use of a phosphor layer to achieve a desired color. Realistic neon-replica LED lighting system 200b may be constructed having any length desired for a given application or design. Notwithstanding, one of ordinary skill in the art, having the benefit of this disclosure, will appreciate that realistic neon-replica LED lighting system 200b may be manufactured in predetermined lengths, each of which may be cut down in size for a specific application or design simply by cutting the desired length off the other distal end, similar to the manner in which a reel of LED strip light may be cut down in size for a given application or design.

Continuing, FIG. 6B shows a detailed view of a second exemplary embodiment 200b of a realistic neon-replica lighting system in accordance with one or more embodiments of the present invention. The flexible LED light engine (e.g., 100b-1, 100b-2) may include a first single-sided, single-row, multi-color LED strip light 100b-1 having a first plurality of multi-color LEDs 130 disposed on a single side of a first flexible substrate 125 and an optional first flexible diffuser layer 135 disposed over the first plurality of multi-color LEDs 130, a second single-sided, single-row, multi-color LED strip light 100b-2 including a second plurality of multi-color LEDs 130 disposed on a single side of a second flexible substrate 125 and an optional second flexible diffuser layer 135 disposed over the second plurality of multi-color LEDs 130. First 100b-1 and second 100b-2 single-sided, single-row, multi-color LED strip lights may be arranged back-to-back with the first plurality of multi-color LEDs 130 of 110b-1 and the second plurality of multi-color LEDs 130 of 110b-2 facing in opposing directions as shown. Flexible binder sleeve 310 may be disposed over first 100b-1 and second 100b-2 single-sided, single-row, multi-color LED strip lights to retain their back-to-back orientation (e.g., FIG. 6C).

In certain embodiments of the present invention, first single-sided, single-row, multi-color LED strip light 100b-1 may include a first flexible diffuser layer 135 disposed over the first plurality of LEDs 130 and second single-sided, single-row, multi-color LED strip light 100b-2 may include a second flexible diffuser layer 135 disposed over the second plurality of LEDs 130. Flexible diffuser layer 135 may include one or more diffusers sufficient to uniformly distribute the light, eliminate hot spots, and create a smooth and continuous glow of light. In such embodiments, optional flexible diffuser sleeve 320 may not be required if the integrated flexible diffuser layer 135 provides sufficient diffusion. The flexible diffuser layer 135 may be embedded in flexible silicone to enhance the light quality and the light efficiency while serving as the flexible and protective medium.

Continuing, FIG. 6C shows a cross-sectional view of a second exemplary embodiment 200b of a realistic neon-replica lighting system in accordance with one or more embodiments of the present invention. First 100b-1 and second 100b-2 single-sided, single-row, multi-color LED strip lights of the flexible LED light engine (e.g., 100b-1, 100b-2) may be arranged in a back-to-back orientation as shown with the first plurality of multi-color LEDs 130 of 100b-1 and the second plurality of multi-color LEDs 130 of 100b-2 facing in opposing directions and held together in the back-to-back-orientation by optional flexible binder sleeve 310.

Optional flexible binder sleeve 310 may be disposed over first 100b-1 and second 100b-2 single-sided, single-row, multi-color LED strip lights to retain their back-to-back orientation. In certain embodiments, flexible binder sleeve 310 may be composed of light transmissible heat-shrink tubing. In other embodiments, flexible binder sleeve 310 may be composed of light transmissible cold-shrink tubing. In still other embodiments, flexible binder sleeve 310 may be composed of light transmissible liquid electrical tape or other sealant. One of ordinary skill in the art, having the benefit of this disclosure, will recognize that flexible binder sleeve 310 may be composed of any other material that provides the requisite structure and light transmissibility while maintaining flexibility and may vary based on an application or design in accordance with one or more embodiments of the present invention.

Optional flexible diffuser sleeve 320 may be disposed over optional flexible binder sleeve 310 and/or the flexible LED light engine (e.g., 100b-1, 100b-2) to uniformly distribute the light, eliminate hot spots, and create a smooth and continuous glow of light. In certain embodiments, flexible diffuser sleeve 320 may be composed of flexible silicone. In other embodiments, flexible diffuser sleeve 320 may be composed of flexible acrylic. In still other embodiments, flexible diffuser sleeve 320 may be composed of flexible polycarbonate or polyethylene terephthalate. One of ordinary skill in the art, having the benefit of this disclosure, will recognize that flexible diffuser sleeve 320 may be composed of any other material that provides the requisite diffusion while maintaining flexibility and may vary based on an application or design in accordance with one or more embodiments of the present invention.

Rigid non-glass transparent tube 330 may be disposed over optional flexible diffuser sleeve 320, optional flexible binder sleeve 310, and/or the flexible LED light engine (e.g., 100b-1, 100b-2).

In certain embodiments, non-glass transparent tube 330 may be composed of acrylic material such as, for example, PMMA, and be transparent, such that realistic neon-replica lighting system 200b replicates the visual appearance of light suspended in glass associated with conventional neon lights.

In other embodiments, non-glass transparent tube 330 may include one or more color dyes dissolved in the acrylic material during formation, by extrusion or casting, of non-glass transparent tube 330, producing a transparent colored tube 330, replicating the visual appearance of phosphor-coated glass tubes associated with a common variation of conventional neon lights.

In still other embodiments, non-glass transparent tube 330 may include one or more color dyes and one or more diffusers dissolved in acrylic material during formation, by extrusion or casting, of non-glass transparent tube 330, producing a translucent colored tube 330, replicating the visual appearance of exterior painted glass tubes associated with another common variation of conventional neon lights.

In certain embodiments, non-glass transparent tube 330 may be composed of polycarbonate material such as, for example, BPA and COCl₂, and be transparent, such that realistic neon-replica lighting system 200b replicates the visual appearance of light suspended in glass associated with conventional neon lights.

In other embodiments, non-glass transparent tube 330 may include one or more color dyes dissolved in the polycarbonate material during formation of non-glass transparent tube 330, producing a transparent colored tube 330, replicating the visual appearance of phosphor-coated glass tubes associated with a common variation of conventional neon lights.

In still other embodiments, non-glass transparent tube 330 may include one or more color dyes and one or more diffusers dissolved in polycarbonate material during formation of non-glass transparent tube 330, producing a translucent colored tube 330, replicating the visual appearance of exterior painted glass tubes associated with another common variation of conventional neon lights.

In one or more embodiments of the present invention, realistic neon-replica LED lighting system 200b has a 360-degree beam angle. So long as each single-sided, single-row, multi-color LED strip light 100b-1, 100b-2 (whether taken alone, with optional flexible diffuser layer 135 disposed on LEDs 130, or in combination with optional flexible diffuser sleeve 320) has a beam angle of 180 degrees, the arrangement of two such LED strip lights 100b-1, 100b-2 back-to-back increases the effective beam angle of the flexible LED light engine (e.g., 100b-1, 100b-2) to 360 degrees, such that it closely mimics the visual appearance of light emanating from all directions of the glass tube of conventional neon lights.

Realistic neon-replica LED lighting system 200b may be rigid when assembled, but rigid non-glass transparent tube 330 may be heated until pliable to aesthetically shape realistic neon-replica LED lighting system 200b. Once it returns to ambient temperature, non-glass transparent tube 330 advantageously returns to rigidity and maintains its shaped form. In this way, realistic neon-replica LED lighting system 200b may be easily shaped into a desired shape or design without requiring the skill or expertise of a skilled glass-bending artisan or the dangerous and complicated process of manufacturing as is required with conventional neon lights. Instead, mere portions of non-glass transparent tube 330 may be heated to the glass transition temperature to become pliable enough to achieve the desired shape or design. Advantageously, realistic neon-replica LED lighting system 200b is rigid upon cooling and fixedly retains its shape, is more durable, lighter, and consumes less power than conventional neon lights, and so closely replicates the appearance of 360-degree continuous glowing light suspended in glass that it is virtually indistinguishable from conventional neon lights.

FIG. 7A shows a perspective view of a third exemplary embodiment 200c of a realistic neon-replica LED lighting system in accordance with one or more embodiments of the present invention. Realistic neon-replica LED lighting system 200c may include a flexible LED light engine (e.g., 100c), an optional flexible diffuser sleeve 320 disposed over the flexible LED light engine (e.g., 100c), and a rigid non-glass transparent tube 330 disposed over optional flexible diffuser sleeve 320 and/or the flexible LED light engine (e.g., 100c).

While the flexible components of realistic neon-replica LED lighting system 200c are flexible by design, rigid non-glass transparent tube 330 is rigid at ambient temperature. However, when heated to its glass transition temperature, rigid non-glass transparent tube 330 becomes pliable and capable of being shaped and returns to rigidity when cooled.

In certain embodiments, rigid non-glass transparent tube 330 may be composed of an acrylic material. Acrylic material used to create rigid non-glass transparent tube 330, may include, for example, PMMA, that has a glass transition temperature in a range between 194 degrees and 239 degrees Fahrenheit. Notwithstanding, one of ordinary skill in the art, having the benefit of this disclosure, will appreciate that the material composition of the acrylic material may vary based on an application or design in accordance with one or more embodiments of the present invention. As discussed in more detail herein, in one or more embodiments of the present invention, rigid non-glass transparent tube 330 may include one or more color dyes and/or one or more diffusers that are dissolved into the acrylic material during formation of rigid non-glass transparent tube 330, typically by extrusion or casting, the content of which may vary the glass transition temperature.

In other embodiments, rigid non-glass transparent tube 330 may be composed of a polycarbonate material. Polycarbonate material may include, for example, BPA and COCl₂ used to create rigid non-glass transparent tube 330 through a polymerization process, that has a glass transition temperature in a range between 284 degrees and 302 degrees Fahrenheit. Notwithstanding, one of ordinary skill in the art, having the benefit of this disclosure, will appreciate that the material composition of the polycarbonate material may vary based on an application or design in accordance with one or more embodiments of the present invention. As discussed in more detail herein, in one or more embodiments of the present invention, rigid non-glass transparent tube 330 may include one or more color dyes and/or one or more diffusers that are dissolved into the polycarbonate material during formation of rigid non-glass transparent tube 330, the content of which may vary the glass transition temperature.

As a multi-color LED 130 embodiment, the flexible LED light engine (e.g., 100c) may include three or more leads depending on the type or kind of multi-color LED as is well known in the art, often including a plurality of electrical leads 210 on a single distal end for connection to the anode (not shown) or the cathode (not shown) of a conventional low voltage DC power supply (not shown), typically in a range between 5- and 24-volts DC, and the others for connection to the red, green, and blue diodes (not independently illustrated) of multi-color LEDs 130. The red, green, and blue diodes (not independently illustrated) of multi-color LEDs 130 are independently controllable such that the flexible LED light engine (e.g., 100c) can produce more than 16 million colors. Realistic neon-replica LED lighting system 200c may be constructed having any length desired for a given application or design. Notwithstanding, one of ordinary skill in the art, having the benefit of this disclosure, will appreciate that realistic neon-replica LED lighting system 200c may be manufactured in predetermined lengths, each of which may be cut down in size for a specific application or design simply by cutting the desired length off the other distal end, similar to the manner in which a reel of LED strip light may be cut down in size for a given application or design.

Continuing, FIG. 7B shows a detailed view of the third exemplary embodiment 200c of a realistic neon-replica lighting system in accordance with one or more embodiments of the present invention. The flexible LED light engine (e.g., 100c) may include a double-sided, single-row, multi-color LED strip light 100c having a first plurality of multi-color LEDs 130 disposed on a first side of double-sided flexible substrate 145 and an optional first flexible diffuser layer 135 disposed over the first plurality of multi-color LEDs 130 and a second plurality of multi-color LEDs 130 disposed on a second side of flexible substrate 145 and an optional second flexible diffuser layer 135 disposed over the second plurality of multi-color LEDs 130. Double-sided, single-row, multi-color LED strip light 100c may, by virtue of its double-sided configuration, include a first plurality of LEDs 135 and a second plurality of LEDs 135 disposed on opposite sides of the same substrate 145 that are facing in opposing directions as shown.

In certain embodiments of the present invention, double-sided, single-row, multi-color LED strip light 100c may include a first flexible diffuser layer 135 disposed over the first plurality of LEDs 130 and a second flexible diffuser layer 135 disposed over the second plurality of LEDs 130. Flexible diffuser layer 135 may include one or more diffusers sufficient to uniformly distribute the light, eliminate hot spots, and create a smooth and continuous glow of light. In such embodiments, optional flexible diffuser sleeve 320 may not be required if the integrated flexible diffuser layer 115 provides sufficient diffusion. The flexible diffuser layer 135 may be embedded in flexible silicone to enhance the light quality and the light efficiency while serving as the flexible and protective medium.

Continuing, FIG. 7C shows a cross-sectional view of the third exemplary embodiment 200c of a realistic neon-replica lighting system in accordance with one or more embodiments of the present invention.

Optional flexible diffuser sleeve 320 may be disposed over the flexible LED light engine (e.g., 100c) to uniformly distribute the light, eliminate hot spots, and create a smooth and continuous glow of light. In certain embodiments, flexible diffuser sleeve 320 may be composed of flexible silicone. In other embodiments, flexible diffuser sleeve 320 may be composed of flexible acrylic. In still other embodiments, flexible diffuser sleeve 320 may be composed of flexible polycarbonate or polyethylene terephthalate. One of ordinary skill in the art, having the benefit of this disclosure, will recognize that flexible diffuser sleeve 320 may be composed of any other material that provides the requisite diffusion while maintaining flexibility and may vary based on an application or design in accordance with one or more embodiments of the present invention.

Rigid non-glass transparent tube 330 may be disposed over optional flexible diffuser sleeve 320, and/or the flexible LED light engine (e.g., 100c).

In certain embodiments, non-glass transparent tube 330 may be composed of acrylic material such as, for example, PMMA, and be transparent, such that realistic neon-replica lighting system 200c replicates the visual appearance of light suspended in glass associated with conventional neon lights.

In other embodiments, non-glass transparent tube 330 may include one or more color dyes dissolved in the acrylic material during formation, by extrusion or casting, of non-glass transparent tube 330, producing a transparent colored tube 330, replicating the visual appearance of phosphor-coated glass tubes associated with a common variation of conventional neon lights.

In still other embodiments, non-glass transparent tube 330 may include one or more color dyes and one or more diffusers dissolved in acrylic material during formation, by extrusion or casting, of non-glass transparent tube 330, producing a translucent colored tube 330, replicating the visual appearance of exterior painted glass tubes associated with another common variation of conventional neon lights.

In certain embodiments, non-glass transparent tube 330 may be composed of polycarbonate material such as, for example, BPA and COCl₂, and be transparent, such that realistic neon-replica lighting system 200c replicates the visual appearance of light suspended in glass associated with conventional neon lights.

In other embodiments, non-glass transparent tube 330 may include one or more color dyes dissolved in the polycarbonate material during formation of non-glass transparent tube 330, producing a transparent colored tube 330, replicating the visual appearance of phosphor-coated glass tubes associated with a common variation of conventional neon lights.

In still other embodiments, non-glass transparent tube 330 may include one or more color dyes and one or more diffusers dissolved in the polycarbonate material during formation of non-glass transparent tube 330, producing a translucent colored tube 330, replicating the visual appearance of exterior painted glass tubes associated with another common variation of conventional neon lights.

In one or more embodiments of the present invention, realistic neon-replica LED lighting system 200c has a 360-degree beam angle. So long as each side of double-sided, single-row, multi-color LED strip light 100c (whether taken alone, with optional flexible diffuser layer 135 disposed on LEDs 130, or in combination with optional flexible diffuser sleeve 320) has a beam angle of 180 degrees, the back-to-back arrangement of the LEDs 130 increases the effective beam angle of the flexible LED light engine (e.g., 100c) to 360 degrees, such that it closely mimics the visual appearance of light emanating from all directions of the glass tube of conventional neon lights.

Realistic neon-replica LED lighting system 200c may be rigid when assembled, but rigid non-glass transparent tube 330 may be heated until pliable to aesthetically shape realistic neon-replica LED lighting system 200c. Once it returns to ambient temperature, non-glass transparent tube 330 advantageously returns to rigidity and maintains its shaped form. In this way, realistic neon-replica LED lighting system 200c may be easily shaped into a desired shape or design without requiring the skill or expertise of a skilled glass-bending artisan or the dangerous and complicated process of manufacturing as is required with conventional neon lights. Instead, mere portions of non-glass transparent tube 330 may be heated to the glass transition temperature to become pliable enough to achieve the desired shape or design. Advantageously, realistic neon-replica LED lighting system 200c is rigid upon cooling and fixedly retains its shape, is more durable, lighter, and consumes less power than conventional neon lights, and so closely replicates the appearance of 360-degree continuous glowing light suspended in glass that it is virtually indistinguishable from conventional neon lights.

FIG. 8A shows a perspective view of a fourth exemplary embodiment of a realistic neon-replica LED lighting system in accordance with one or more embodiments of the present invention. Realistic neon-replica LED lighting system 200d may include a flexible LED light engine (e.g., 100d in a folded back-to-back arrangement), an optional flexible binder sleeve 310 disposed over the flexible LED light engine (e.g., 100d), an optional flexible diffuser sleeve 320 disposed over optional flexible binder sleeve 310 and/or the flexible LED light engine (e.g., 100d), and a rigid non-glass transparent tube 330 disposed over optional flexible diffuser sleeve 320, optional flexible binder sleeve 310, and the LED light engine (e.g., 100d).

While the flexible components of realistic neon-replica LED lighting system 200d are flexible by design, rigid non-glass transparent tube 330 is rigid at ambient temperature. However, when heated to its glass transition temperature, rigid non-glass transparent tube 330 becomes pliable and capable of being shaped and returns to rigidity when cooled to ambient temperature.

In certain embodiments, rigid non-glass transparent tube 330 may be composed of an acrylic material. Acrylic material used to create rigid non-glass transparent tube 330, may include, for example, PMMA, that has a glass transition temperature in a range between 194 degrees and 239 degrees Fahrenheit. Notwithstanding, one of ordinary skill in the art, having the benefit of this disclosure, will appreciate that the material composition of the acrylic material may vary based on an application or design in accordance with one or more embodiments of the present invention. As discussed in more detail herein, in one or more embodiments of the present invention, rigid non-glass transparent tube 330 may include one or more color dyes and/or one or more diffusers that are dissolved into the acrylic material during formation of rigid non-glass transparent tube 330, typically by extrusion or casting, the content of which may vary the glass transition temperature.

In other embodiments, rigid non-glass transparent tube 330 may be composed of a polycarbonate material. Polycarbonate material may include, for example, BPA and COCl₂ used to create rigid non-glass transparent tube 330 through a polymerization process, that has a glass transition temperature in a range between 284 degrees and 302 degrees Fahrenheit. Notwithstanding, one of ordinary skill in the art, having the benefit of this disclosure, will appreciate that the material composition of the polycarbonate material may vary based on an application or design in accordance with one or more embodiments of the present invention. As discussed in more detail herein, in one or more embodiments of the present invention, rigid non-glass transparent tube 330 may include one or more color dyes and/or one or more diffusers that are dissolved into the polycarbonate material during formation of rigid non-glass transparent tube 330, the content of which may vary the glass transition temperature.

In single-color LED 110 embodiments, the flexible LED light engine (e.g., 100d) may include two electrical leads 210 on a single distal end for connection to the anode (not shown) and the cathode (not shown) of a conventional low voltage DC power supply (not shown), typically in a range between 5- and 24-volts DC.

In multi-color LED 130 embodiments, the flexible LED light engine (e.g., 100d) may include three or more leads depending on the type or kind of multi-color LED as is well known in the art, often including a plurality of electrical leads 210 on a single distal end for connection to the anode (not shown) or the cathode (not shown) of a conventional low voltage DC power supply (not shown), typically in a range between 5- and 24-volts DC, and the others for connection to the red, green, and blue diodes (not independently illustrated) of multi-color LEDs 130. The red, green, and blue diodes (not independently illustrated) of multi-color LEDs 130 are independently controllable such that the flexible LED light engine (e.g., 100d) can produce more than 16 million colors without requiring the use of a phosphor layer to achieve a desired color.

Realistic neon-replica LED lighting system 200d may be constructed having any desired length for a given application or design. Notwithstanding, one of ordinary skill in the art, having the benefit of this disclosure, will appreciate that realistic neon-replica LED lighting system 200d may be manufactured in predetermined lengths, each of which may be cut down in size for a specific application or design simply by cutting the desired length off the other distal end, similar to the manner in which a reel of LED strip light may be cut down in size for a given application or design.

Continuing, FIG. 8B shows a detailed view of the fourth exemplary embodiment of a realistic neon-replica lighting system in accordance with one or more embodiments of the present invention. The flexible LED light engine (e.g., 100d) may include a single-sided, dual-row, single-color or multi-color LED strip light 100d having a first plurality of single-color 110 or multi-color 130 LEDs arranged in a first row disposed on a left side 150a of a flexible bend line 155 of a first side of flexible substrate 150 and a second plurality of single-color 110 or multi-color 130 LEDs arranged in a second row disposed on a right side 150b of the flexible bend line 155 of the first side of flexible substrate 150. Flexible substrate 150 may be folded along the flexible bend line 155 that extends along the longitudinal length of substrate 150. A first optional flexible phosphor and/or diffuser layer 115 may be disposed over the first plurality of single-color 110 or multi-color 130 LEDs arranged in the first row and a second optional flexible phosphor and/or diffuser layer 115 may be disposed over the second plurality of single-color 110 or multi-color 130 LEDs arranged in the second row. Flexible binder sleeve 310 may be disposed over the folded arrangement of flexible LED light engine 100d to retain the back-to-back orientation of LEDs 110/130 that are facing in opposing directions (e.g., FIG. 8C).

In certain embodiments of the present invention, the single-sided, dual-row, single-color or multi-color LED strip light 100d may include a first flexible phosphor layer 115 disposed over the first plurality of LEDs 110/130 arranged in the first row and a second flexible phosphor layer 115 disposed over the second plurality of LEDs 110/130 arranged in the second row. Each flexible phosphor layer 115 may include one or more phosphors sufficient to achieve the desired color of visible light emitted.

In other embodiments of the present invention, the single-sided, dual-row, single-color or multi-color LED strip light 100d may include a first flexible diffuser layer 115 disposed over the first plurality of LEDs 110/130 arranged in the first row and a second flexible diffuser layer 115 disposed over the second plurality of LEDs 110/130 arranged in the second row. Each flexible diffuser layer 115 may include one or more diffusers sufficient to uniformly distribute the light, eliminate hot spots, and create a smooth and continuous glow of light. In such embodiments, optional flexible diffuser sleeve 320 may not be required if the integrated flexible diffuser layer 115 provides sufficient diffusion.

In still other embodiments of the present invention, the single-sided, dual-row, single-color or multi-color LED strip light 100d may include a first flexible phosphor and diffuser layer 115 disposed over the first plurality of LEDs 110/130 arranged in the first row and a second flexible phosphor and diffuser layer 115 disposed over the second plurality of LEDs 110/130 arranged in the second row. Each flexible phosphor and diffuser layer 115 may include one or more phosphors sufficient to achieve the desired color of light and one or more diffusers sufficient to uniformly distribute the light, eliminate hot spots, and create a smooth and continuous glow of light. In such embodiments, optional flexible diffuser sleeve 320 may not be required as the flexible phosphor and diffuser layer 115 integrated with LED strip light 100d may provide sufficient diffusion.

In each of the embodiments noted above, the one or more phosphors and the one or more diffusers may be embedded in flexible silicone to enhance the light quality and the light efficiency, while serving as the flexible and protective medium.

Continuing, FIG. 8C shows a cross-sectional view of the fourth exemplary embodiment of a realistic neon-replica lighting system in accordance with one or more embodiments of the present invention. The single-sided, dual-row, single-color or multi-color LED strip light 100d of the flexible LED light engine (e.g., 100d) may be in a folded arrangement such that the LEDs disposed on the left and right side of the same side of flexible substrate 150 are now facing in opposite directions and held together in the back-to-back-orientation by optional flexible binder sleeve 310.

Optional flexible binder sleeve 310 may be disposed over the folded arrangement of the single-sided, dual row, single-color or multi-color LED strip light 100d to retain the back-to-back orientation of the LEDs facing in opposing directions. In certain embodiments, flexible binder sleeve 310 may be composed of light transmissible heat-shrink tubing. In other embodiments, flexible binder sleeve 310 may be composed of light transmissible cold-shrink tubing. In still other embodiments, flexible binder sleeve 310 may be composed of light transmissible liquid electrical tape or other sealant. One of ordinary skill in the art, having the benefit of this disclosure, will recognize that flexible binder sleeve 310 may be composed of any other material that provides the requisite structure and light transmissibility while maintaining flexibility and may vary based on an application or design in accordance with one or more embodiments of the present invention.

Optional flexible diffuser sleeve 320 may be disposed over the optional flexible binder sleeve 310 and/or the flexible LED light engine (e.g., 100d) to uniformly distribute the light, eliminate hot spots, and create a smooth and continuous glow of light. In certain embodiments, flexible diffuser sleeve 320 may be composed of flexible silicone. In other embodiments, flexible diffuser sleeve 320 may be composed of flexible acrylic. In still other embodiments, flexible diffuser sleeve 320 may be composed of flexible polycarbonate or polyethylene terephthalate. One of ordinary skill in the art, having the benefit of this disclosure, will recognize that flexible diffuser sleeve 320 may be composed of any other material that provides the requisite diffusion while maintaining flexibility and may vary based on an application or design in accordance with one or more embodiments of the present invention.

Rigid non-glass transparent tube 330 may be disposed over optional flexible diffuser sleeve 320, optional flexible binder sleeve 310, and/or the flexible LED light engine (e.g., 100d). In certain embodiments, non-glass transparent tube 330 may be composed of acrylic material such as, for example, PMMA, and be transparent, such that realistic neon-replica lighting system 200a replicates the visual appearance of light suspended in glass associated with conventional neon lights. In other embodiments, non-glass transparent tube 330 may include one or more color dyes dissolved in the acrylic material during formation of non-glass transparent tube 330, by extrusion or casting, producing a transparent colored tube 330, replicating the visual appearance of phosphor-coated glass tubes associated with a common variation of conventional neon lights. In still other embodiments, non-glass transparent tube 330 may include one or more color dyes and one or more diffusers dissolved in acrylic material during formation of non-glass transparent tube 330, by extrusion or casting, producing a translucent colored tube 330, replicating the visual appearance of exterior coated glass tubes associated with another common variation of conventional neon lights.

In one or more embodiments of the present invention, realistic neon-replica LED lighting system 200d has a 360-degree beam angle. So long as the first plurality of LEDs 110/130 arranged in the first row and the second plurality of LEDs 110/130 arranged in the second row (whether taken alone, with optional flexible phosphor and/or diffuser layers 115 disposed on each row of LEDs 110/130, or in combination with optional flexible diffuser sleeve 320) has a beam angle of 180 degrees, the folded arrangement of LED strip light 100d increases the effective beam angle of the flexible LED light engine (e.g., 100d) to 360 degrees, such that it closely mimics the visual appearance of light emanating from all directions of the glass tube of conventional neon lights.

Realistic neon-replica LED lighting system 200d may be rigid when assembled, but rigid non-glass transparent tube 330 may be heated until pliable to aesthetically shape realistic neon-replica LED lighting system 200d. Once it returns to ambient temperature, non-glass transparent tube 330 advantageously returns to rigidity and maintains its shaped form. In this way, realistic neon-replica LED lighting system 200d may be easily shaped into a desired shape or design without requiring the skill or expertise of a skilled glass-bending artisan or the dangerous and complicated process of manufacturing as is required with conventional neon lights. Instead, mere portions of non-glass transparent tube 330 may be heated to the glass transition temperature to become pliable enough to achieve the desired shape or design. Advantageously, realistic neon-replica LED lighting system 200d is rigid upon cooling to ambient temperature and fixedly retains its shape, is more durable, lighter, and consumes less power than conventional neon lights, and so closely replicates the appearance of 360-degree continuous glowing light suspended in glass that it is virtually indistinguishable from conventional neon lights.

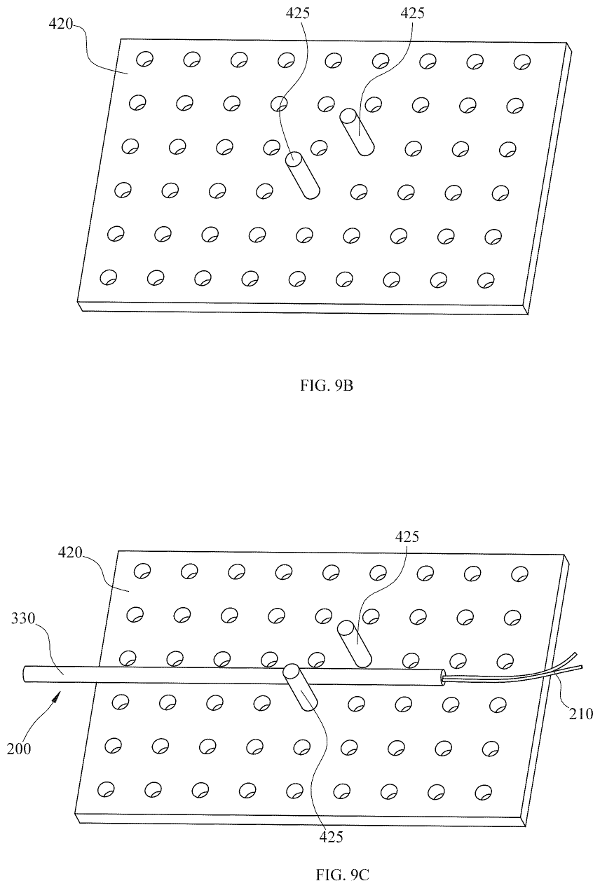

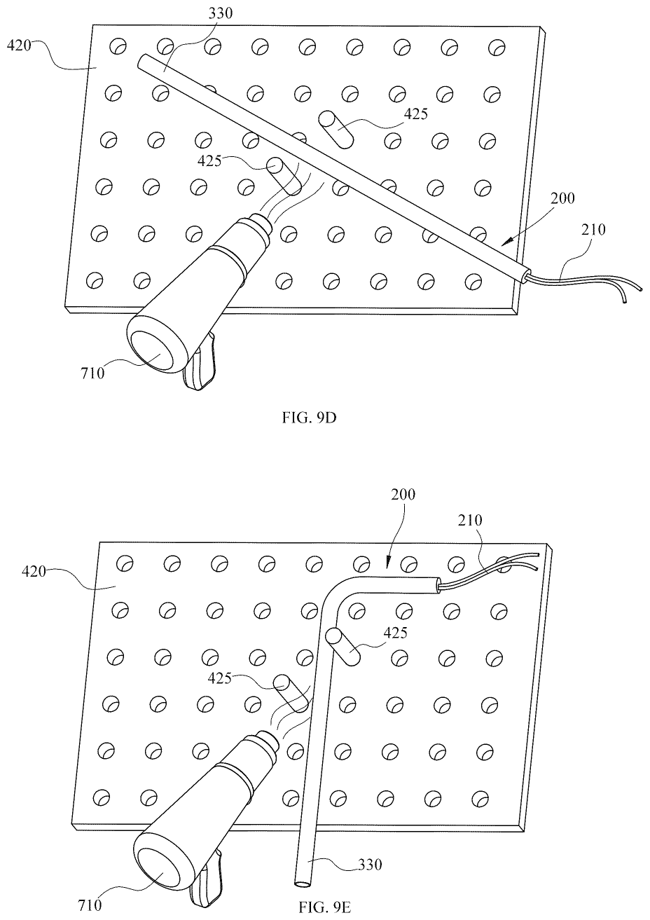

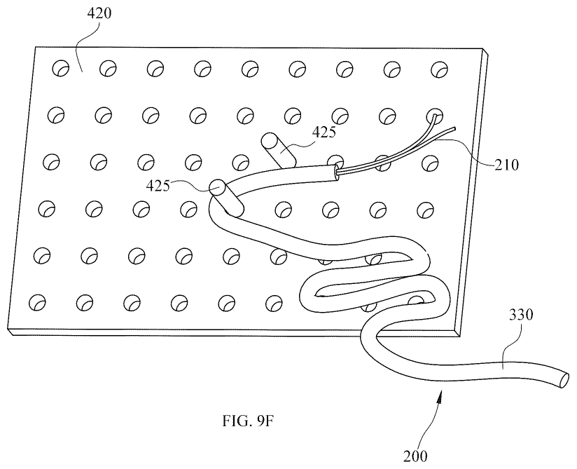

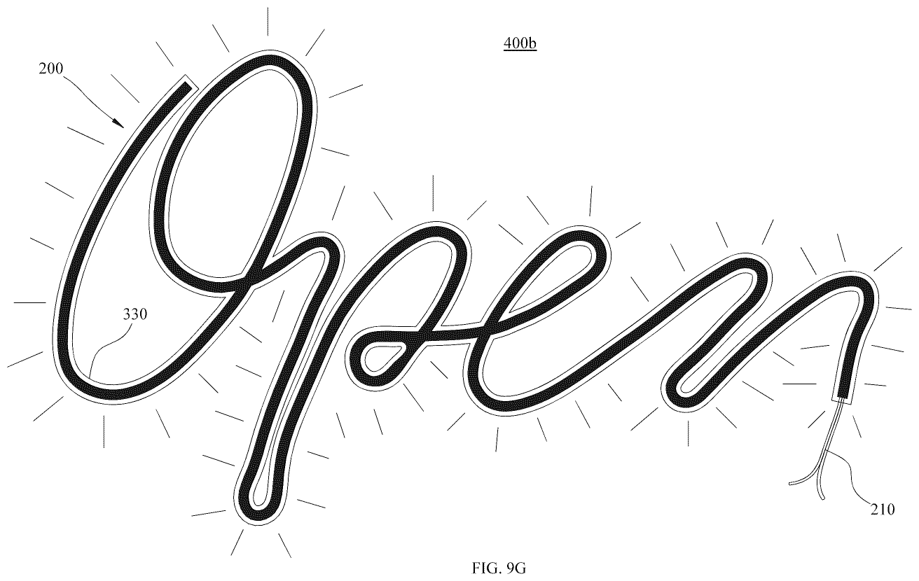

FIG. 9A shows an example of a conventional neon light 400a. Conventional neon light 400a includes a sealed glass tube 405 containing noble gas (not shown), a first electrode 410a disposed on a first distal end of glass tube 405, and a second electrode 410b disposed on a second distal end of glass tube 405. First electrode 410a includes electrical leads 415a for connection to a high voltage step-up transformer (not shown) that steps up the voltage to thousands of volts. When powered, the pair of electrodes 410a, 410b ionize the noble gas (not shown) disposed within glass tube 405. In operative use, conventional neon light 400a is fragile as it is primarily made of gas, requires dangerously high voltages on the order of magnitude of thousands of volts, consumes significant power, produces significant heat, and includes hazardous materials that are toxic to humans.

Additionally, the process of manufacturing conventional neon light 400a is complex, time-consuming, and difficult. Bending glass tube 405 into a desired shape requires a high degree of skill and expertise from a dwindling population of skilled glass-bending artisans. Once shaped, glass tube 405 must be carefully filled with noble gas (not shown) and hazardous materials like mercury (not shown). Electrodes 410a, 410b must be carefully attached to ensure that the distal ends of glass tube 405 are effectively sealed to prevent the leakage. Since the process typically includes hazardous materials, careful handling and disposal are required throughout the process to prevent exposure and minimize environmental impacts. Furthermore, conventional neon light 400a also requires the acquisition of high-purity noble gas. As noted above, a significant amount of the world's neon supply comes from Ukraine, which is currently at war. These factors make the process of manufacturing conventional neon light 400a complex, time-consuming, and difficult, requiring skilled labor, careful handling and disposal of hazardous materials, and challenging supply chains.

Continuing, FIG. 9B shows a forming jig 420 for shaping a realistic neon-replica LED lighting system (e.g., any 200) in accordance with one or more embodiments of the present invention. Forming jig 420 is a well-known tool in the art that is typically used to bend or shape metals, plastics, or wood. In this example, forming jig 420 may be a peg board with one or more pegs 425 disposed at desired locations for shaping. One of ordinary skill in the art will recognize that any type or kind of forming jig that provides the requisite fixtures for shaping the realistic neon-replica LED lighting system (e.g., 200) may be used in accordance with one or more embodiments of the present invention.

Continuing, FIG. 9C shows the introduction of realistic neon-replica LED lighting system 200 to forming jig 420 in anticipation of shaping in accordance with one or more embodiments of the present invention. In one or more embodiments of the present invention, a method of making realistic neon-replica LED lighting system 200 includes disposing the flexible LED light engine in the optional flexible diffuser sleeve (e.g., 320) and disposing the flexible diffuser sleeve (e.g., 320) or the flexible LED Light engine itself in rigid non-glass transparent tube 330. Realistic neon-replica LED lighting system 200 may be positioned with respect to the one or more jigs 425 on forming jig 420 for shaping. Continuing, FIG. 9D shows the application of heat to realistic neon-replica LED lighting system 200 in anticipation of shaping a first exemplary bend in accordance with one or more embodiments of the present invention. While rigid non-glass transparent tube 330 of realistic neon-replica LED lighting system 200 is rigid at ambient temperature, it becomes pliable when heated. As such, realistic neon-replica LED lighting system 200 may be heated for shaping. In certain embodiments, heat may be applied by a heat gun 710 in only those locations of realistic neon-replica LED lighting system 200 where shaping is desired. In other embodiments, the entire realistic neon-replica LED lighting system 200 may be subjected to heat via a heating tube (not shown) or other means of heating the entire assembly 200. Notwithstanding, one of ordinary skill in the art, having the benefit of this disclosure will appreciate that other ways of applying heat may be employed in accordance with one or more embodiments of the present invention. Once heated, realistic neon-replica LED lighting system 200 may be shaped by manipulating it against the fixed jigs 425 of forming jig 420, resulting in one or more arcuate bends that achieve the desired shape or pattern.

Continuing, FIG. 9E shows the application of heat 710 to realistic neon-replica LED lighting system 200 in anticipation of shaping a second exemplary bend in accordance with one or more embodiments of the present invention. After having made the first exemplary bend, non-glass transparent tube 330 of realistic neon-replica LED lighting system 200 cools off and the first exemplary bend returns to rigidity such that it is locked into place. The process of heating realistic neon-replica LED lighting system 200 in a location where shaping is desired may be repeated as many times as necessary to achieve a desired shape or pattern. Here, after having made a first exemplary bend, a different location is heated in anticipation of forming the second exemplary bend. Continuing, FIG. 9F shows the application of heat 710 to realistic neon-replica LED lighting system 200 in anticipation of shaping a third exemplary bend in accordance with one or more embodiments of the present invention. Here, further bends are illustrated in an effort to achieve a desired shape or pattern. It is important to note that the process of heating and shaping non-glass transparent tube 330 of realistic neon-replica LED lighting system 200 does not require the expertise or skill of a skilled glass-bending artisan nor is there any exposure to fragile and breakable glass, high voltages, high-purity noble gases, or hazardous materials.

Continuing, FIG. 9G shows the shaped 400b realistic neon-replica LED lighting system 200 replicating neon light 400a of FIG. 9A in accordance with one or more embodiments of the present invention. In operative use, shaped 400b realistic neon-replica LED lighting system 200 is virtually indistinguishable from neon light 400a of FIG. 9A. The disposition of the flexible LED light engine in the flexible diffuser sleeve (e.g., 320) generates warm, continuous, and glowing light with a 360-degree beam angle that replicates the 360-degrees of glowing light generated by excited noble gases suspended within the sealed glass tube of conventional neon lights. The disposition of the flexible diffuser sleeve (e.g., 320) in non-glass transparent tube 330 replicates the visual appearance of light suspended in air associated with conventional neon lights 400a. Further, the flexible LED light engine may, through the use of single-color LEDs and flexible phosphor layers or multi-color LEDs, achieve virtually any desired color. In this way, realistic neon-replica LED lighting system 400b so closely replicates the appearance of conventional neon lights 400a, that realistic neon-replica LED lighting system 400b or portions thereof may be used to repair portions of a damaged conventional neon light 400a in a manner that is not noticeable to those who gaze upon it, even when viewed up close. Advantageously, shaped realistic neon-replica LED lighting system 400b is more durable, weighs less, employs low voltage, consumes significantly less power, generates significantly less heat, does not require high-purity noble gases, or hazardous materials.

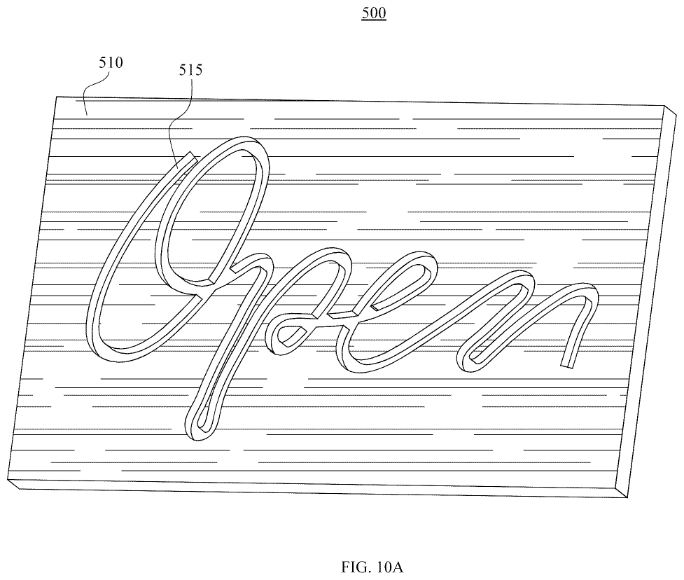

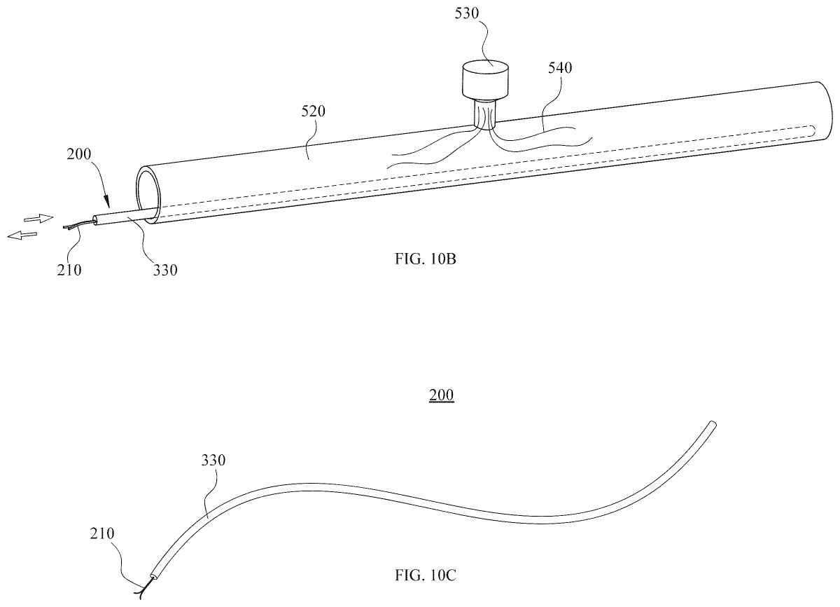

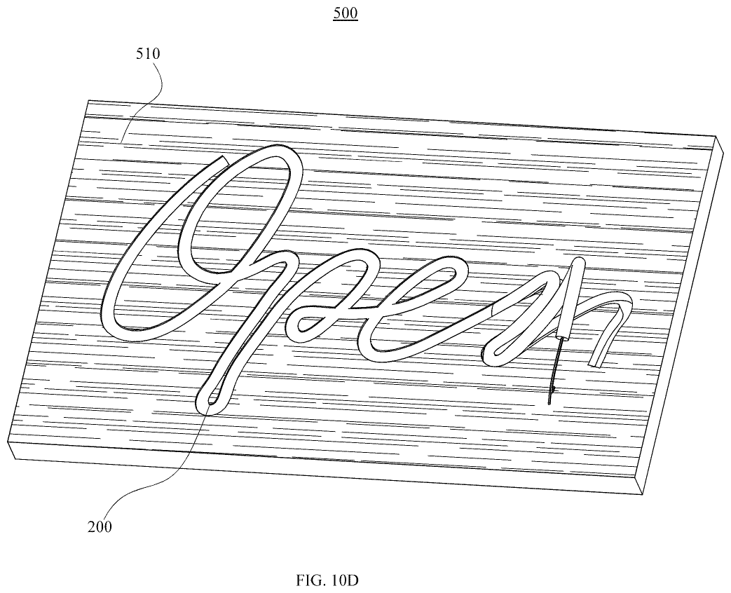

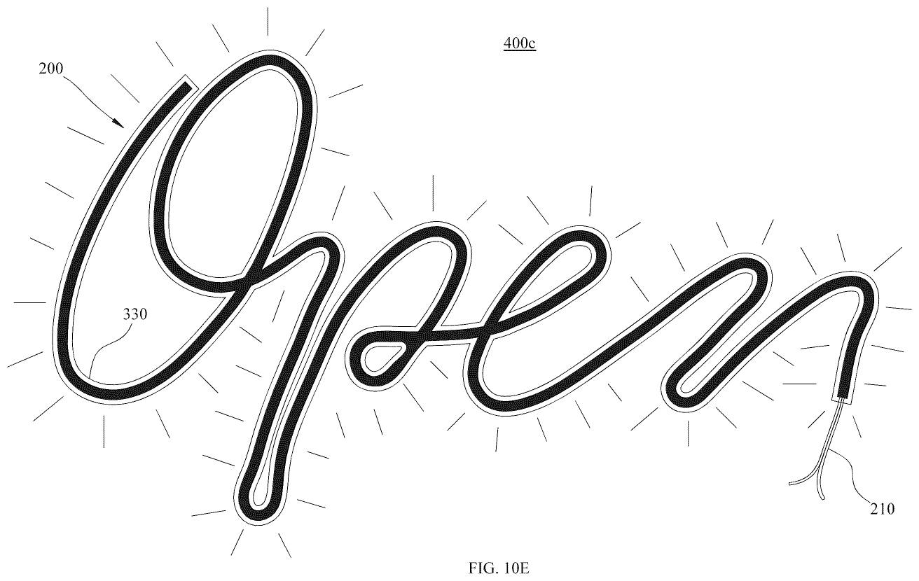

FIG. 10A shows a recessed forming board 510 for making a realistic neon-replica LED lighting system in accordance with one or more embodiments of the present invention. While the use of a heat gun (e.g., 710 of FIG. 9) and a forming jig (e.g., 420 of FIG. 9) to shape a realistic neon-replica LED lighting system (e.g., 200) into a desired shape is feasible for relatively small numbers, it may not be efficient for high volume applications. A recessed forming board 510 includes a recessed portion 515 in the shape of the desired product. As shown in the figure, the exemplary recessed forming board 510 includes a recessed portion 515 that matches that of conventional neon light 400a of FIG. 9A. Continuing, FIG. 10B shows a heating tube 520 for heating realistic neon-replica LED lighting system 200 in accordance with one or more embodiments of the present invention. While merely exemplary, heating tube 520 may include heat source 530 that generates heat 540 within the interior of tube 520. In this way, realistic neon-replica LED lighting system 200 may be disposed within the interior of heating tube 520 such that a significant portion or all of non-glass transparent tube 330 of neon-replica LED lighting system 200 is heated to the extent necessary to become pliable.

Continuing, FIG. 10C shows a heated and pliable realistic neon-replica LED lighting system 200 in accordance with one or more embodiments of the present invention. After heating, neon-replica LED lighting system 200 may be flexible and pliable for a period of time after heating that permits shaping it. Continuing, FIG. 10D shows the heated and pliable realistic neon-replica LED lighting system 200 being introduced to recessed portions 515 of recessed forming board 510 to provide the exemplary shape in accordance with one or more embodiments of the present invention. In the heated and pliable state, neon-replica LED lighting system 200 may be easily placed within the recessed portions 515 of recessed forming board 510 to apply the requisite shape to lighting system 200. After cooling to ambient temperature, non-glass transparent tube 330 of neon-replica LED lighting system 200 returns to rigidity and retains its shape, matching that of conventional neon light 400a.

Continuing, FIG. 10E shows the realistic neon-replica LED lighting system 400c replicating neon light 400a of FIG. 9A in accordance with one or more embodiments of the present invention. In operative use, shaped realistic neon-replica LED lighting system 400b is virtually indistinguishable from neon light 400a of FIG. 9A. The disposition of the flexible LED light engine in the flexible diffuser sleeve (e.g., 320) generates warm, continuous, and glowing light with a 360-degree beam angle that replicates the 360-degrees of glowing light generated by excited noble gases suspended with a glass tube. The disposition of the flexible diffuser sleeve (e.g., 320) in non-glass transparent tube 330 replicates the visual appearance of light suspended in air associated with conventional neon lights 400a. Further, the flexible LED light engine may, through the use of phosphor coatings, filtered light coatings, or the use of multi-color LEDs, achieve virtually any desired color. In this way, realistic neon-replica LED lighting system 400b so closely replicates the appearance of conventional neon lights 400a, that neon-replica LED lighting system 400b or portions thereof may be used to repair portions of a damaged neon light 400a in a manner that is not noticeable to those who look upon it. Advantageously, shaped realistic neon-replica LED lighting system 400b is more durable, weighs less, low voltage, consumes significantly less power, generates significantly less heat, does not require high-purity noble gases, or hazardous materials.

Advantages of one or more embodiments of the present invention may include one or more of the following:

In one or more embodiments of the present invention, a realistic neon-replica LED lighting system more closely mimics the well-known, readily identifiable, and iconic visual appearance of conventional neon lights. Despite prior art attempts at replicating conventional neon lights, the realistic neon-replica LED lighting system of the claimed invention is the first and only replica that is virtually indistinguishable from conventional neon lights, even when viewed up close.

In one or more embodiments of the present invention, a realistic neon-replica LED lighting system is significantly easier to manufacture compared to conventional neon lights. The realistic neon-replica LED lighting system uses a low voltage LED light engine, eliminating the need for, and handling of, fragile glass tubes, high voltage transformers, electrodes, high purity noble gases, or hazardous materials like mercury. Additionally, the realistic neon-replica LED lighting system uses a non-glass transparent tube that is more durable and significantly easier to shape into a desired form, without requiring the expertise of a skilled glass-bending artisan. Furthermore, the realistic neon-replica LED lighting system uses commonly available components that are more easily acquired, handled, and assembled than those used in conventional neon lights.

In one or more embodiments of the present invention, a realistic neon-replica LED lighting system is significantly safer to manufacture compared to conventional neon lights. This realistic neon-replica LED lighting system uses a low voltage LED light engine, eliminating the need for, and handling of, high voltage transformers, electrodes, high purity noble gases, or hazardous materials like mercury. Additionally, the realistic neon-replica LED lighting system uses a non-glass transparent tube that is more durable and less prone to breakage than the fragile glass tubes used in conventional neon lights. In operation, the realistic neon-replica LED lighting system consumes less power, generates less heat, and reduces the risk of fire hazards.

In one or more embodiments of the present invention, a realistic neon-replica LED lighting system costs significantly less to manufacture compared to conventional neon lights. As noted above, the realistic neon-replica LED lighting system does not require expensive high voltage transformers, electrodes, high purity noble gases, or hazardous materials like mercury that require special handling and disposal processes. Additionally, the use of durable and easily shaped non-glass transparent tubes instead of fragile glass tubes further simplifies the manufacturing process and reduces labor costs, as it does not require the expertise of skilled glass-bending artisans. Moreover, the components of the realistic neon-replica LED lighting system are more widely available and are mass produced leading to economies of scale that significantly lower production costs. These factors and others significantly reduce the cost of manufacturing the realistic neon-replica LED lighting system compared to conventional neon lights.

In one or more embodiments of the present invention, a realistic neon-replica LED lighting system is safer, easier, and costs less to operate compared to conventional neon lights. As noted above, the realistic neon-style LED lighting system does not use high voltage components, consumes less power, and dissipates less heat compared to conventional neon lights. Even in the event of a failure, the realistic neon-replica LED lighting system does not expose anyone to high voltages, broken glass, high-purity noble gases, or toxic substances.

In one or more embodiments of the present invention, a realistic neon-replica LED lighting system offers numerous advantages over conventional neon lights including longer lifespan, more color options, increased durability, greater energy efficiency, faster production time, and low voltage operation for enhanced safety. Additionally, the realistic neon-replica LED lighting system uniquely enables color changing, color chasing, higher lumens for increased brightness, lower environmental impact, reduced heat generation, easier installation and maintenance, simplified controls, lighter weight and improved portability.

While the present invention has been described with respect to the above-noted embodiments, those skilled in the art, having the benefit of this disclosure, will recognize that other embodiments may be devised that are within the scope of the invention as disclosed herein. Accordingly, the scope of the invention should only be limited by the appended claims.

1. A neon-replica LED lighting system comprising:
a flexible LED light engine;
a flexible diffuser sleeve disposed over the flexible LED light engine; and
a rigid non-glass transparent tube disposed over the flexible LED light engine, wherein the rigid non-glass transparent tube comprises an acrylic material with one or more color dyes and one or more diffusers dissolved in the acrylic material during formation of the non-glass transparent tube, producing a translucent colored tube,
wherein the rigid non-glass transparent tube is pliable when heated to its glass transition temperature and returns to rigidity when cooled, and
wherein the neon-replica LED lighting system has a 360 degree beam angle.

2. (canceled)

3. (canceled)

4. The neon-replica LED lighting system of claim 1, wherein the rigid non-glass transparent tube comprises one or more color dyes dissolved in the acrylic material during formation of the non-glass transparent tube, producing a transparent colored tube.

5. (canceled)

6. The neon-replica LED lighting system of claim 1, wherein the rigid non-glass transparent tube comprises a polycarbonate material.

7. The neon-replica LED lighting system of claim 6, wherein the rigid non-glass transparent tube comprises one or more color dyes dissolved in the polycarbonate material during formation of the transparent tube, producing a non-glass transparent colored tube.

8. The neon-replica LED lighting system of claim 6, wherein the rigid non-glass transparent tube comprises one or more color dyes and one or more diffusers dissolved in the polycarbonate material during formation of the non-glass transparent tube, producing a translucent colored tube.

9. The neon-replica LED lighting system of claim 1, wherein the flexible LED light engine comprises:
a first single-sided LED strip light comprising a first plurality of LEDs disposed on a single side of a first flexible substrate;
a second single-sided LED strip light comprising a second plurality of LEDs disposed on a single side of a second flexible substrate; and
a flexible binder sleeve,
wherein the first and the second single-sided LED strip lights are arranged back-to-back with the first plurality of LEDs and the second plurality of LEDs facing in opposing directions and held together in the back-to-back arrangement by the flexible binder sleeve.

10. The neon-replica LED lighting system of claim 9, wherein the first plurality and the second plurality of LEDs are single-color LEDs.

11. The neon-replica LED lighting system of claim 9, wherein the first plurality and the second plurality of LEDs are multi-color LEDs.

12. The neon-replica LED lighting system of claim 9,
wherein the first single-sided LED strip light further comprises a first flexible phosphor layer disposed over the first plurality of LEDs, and
wherein the second single-sided LED strip light further comprises a second flexible phosphor layer disposed over the second plurality of LEDs.

13. The neon-replica LED lighting system of claim 9,
wherein the first single-sided LED strip light further comprises a first flexible diffuser layer disposed over the first plurality of LEDs,
wherein the second single-sided LED strip light further comprises a second flexible diffuser layer disposed over the second plurality of LEDs, and
wherein the neon-replica LED lighting system has a 360-degree beam angle.

14. The neon-replica LED lighting system of claim 9,
wherein the first single-sided LED strip light further comprises a first flexible phosphor and diffuser layer disposed over the first plurality of LEDs, and
wherein the second single-sided LED strip light further comprises a second flexible phosphor and diffuser layer disposed over the second plurality of LEDs,
wherein the neon-replica LED lighting system has a 360-degree beam angle.

15. The neon-replica LED lighting system of claim 1, wherein the flexible LED light engine comprises:
a double-sided flexible substrate,
a first plurality of LEDs disposed on a first side of the double-sided flexible substrate, and
a second plurality of LEDs disposed on a second side of the double-sided flexible substrate,
wherein the first plurality of LEDs and the second plurality of LEDs are facing in opposing directions.

16. The neon-replica LED lighting system of claim 15, wherein the first plurality and the second plurality of LEDs are single-color LEDs.

17. The neon-replica LED lighting system of claim 15, wherein the first plurality and the second plurality of LEDs are multi-color LEDs.

18. The neon-replica LED lighting system of claim 15, wherein the flexible LED light engine further comprises:
a first flexible phosphor layer disposed over the first plurality of LEDs, and
a second flexible phosphor layer disposed over the second plurality of LEDs.

19. The neon-replica LED lighting system of claim 15, wherein the flexible LED light engine further comprises:
a first flexible diffuser layer disposed over the first plurality of LEDs, and
a second flexible diffuser layer disposed over the second plurality of LEDs,
wherein the neon-replica LED lighting system has a 360-degree beam angle.

20. The neon-replica LED lighting system of claim 15, wherein the flexible LED light engine further comprises:
a first flexible phosphor and diffuser layer disposed over the first plurality of LEDs, and
a second flexible phosphor and diffuser layer disposed over the second plurality of LEDs,
wherein the neon-replica LED lighting system has a 360-degree beam angle.

21. The neon-replica LED lighting system of claim 1, wherein the flexible LED light engine comprises:
a singled-side LED strip light comprising a first plurality of LEDs arranged in a first row disposed on a left side of a single side of a flexible substrate, a longitudinal bend line, and a second plurality of LEDs arranged in a second row disposed on a right side of the single side of the flexible substrate;
a flexible binder sleeve,
wherein the single-sided LED strip light is folded along the longitudinal bend line such that the first plurality of LEDs and the second plurality of LEDs are arranged back-to-back with the first plurality of LEDs and the second plurality of LEDs facing in opposing directions and held together in the back-to-back arrangement by the flexible binder sleeve.

22. The neon-replica LED lighting system of claim 21, wherein the first plurality and the second plurality of LEDs are single-color LEDs.

23. The neon-replica LED lighting system of claim 21, wherein the first plurality and the second plurality of LEDs are multi-color LEDs.

24. The neon-replica LED lighting system of claim 21,
wherein the single-sided LED strip light further comprises a first flexible phosphor layer disposed over the first plurality of LEDs and a second flexible phosphor layer disposed over the second plurality of LEDs.

25. The neon-replica LED lighting system of claim 21,
wherein the single-sided LED strip light further comprises a first flexible diffuser layer disposed over the first plurality of LEDs and a second flexible diffuser layer disposed over the second plurality of LEDs, and
wherein the neon-replica LED lighting system has a 360-degree beam angle.

26. The neon-replica LED lighting system of claim 21,
wherein the single-sided LED strip light further comprises a first flexible phosphor and diffuser layer disposed over the first plurality of LEDs and a second flexible phosphor and diffuser layer disposed over the second plurality of LEDs, and
wherein the neon-replica LED lighting system has a 360-degree beam angle.
